(19) United States
(12) Patent Application Publication
(10) Pub. No.: US 2026/0206287 A1
(43) Pub. Date: Jul. 16, 2026

(54) METHOD AND STRUCTURE FOR REDUCING INDUCED CHARGE IN A SUBSTRATE

(71) Applicant: Taiwan Semiconductor Manufacturing Co., Ltd., Hsinchu (TW)

(72) Inventors: Chia-Yu Fang, Hsinchu County (TW); Chung-Ting Ko, Kaohsiung (TW); Po-Cheng Shih, Hsinchu (TW); Tze-Liang Lee, Hsinchu (TW)

(21) Appl. No.: 19/020,172

(22) Filed: Jan. 14, 2025

(51) Int. Cl. H10D 84/01; H10D 84/83

(52) U.S. Cl. CPC H10D 84/0153; H10D 84/832

(57) ABSTRACT

A method that includes etching at least one conductive structure to form an opening separating the conductive structure into shorter portions; and applying at least one passivation treatment to an upper portion of the opening. The method can also include forming a non-conformal material layer having a lower fixed charge concentration than silicon nitride. In some embodiments, the non-conformal material layer has a first portion on the upper portion of the opening passivated by the at least one passivation treatment, and the non-conformal layer has a second portion that extends to the base of the opening, the first portion of the non-conformal material layer having a lesser thickness than the second portion of the non-conformal material layer. In some embodiments, the method further includes depositing a fill dielectric on the non-conformal material layer.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, for the purposes of device isolation, dielectrics such as dielectric materials, can be used for spacers, liner and gap fill materials. However, in some instances, dielectric materials can have a high level of positive fixed charge, resulting from point defects. In some instances, high levels of positive fixed charge within semiconductor devices may cause multiple device performance issues.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 10C, 11, 18A, 18B, 19A, 19B, 20, 37A, 37B, 38A and 38B illustrate the views of intermediate stages in the formation of transistors in accordance with some embodiments.

FIGS. 12A, 12B, 13A, 13B, 14A, 14B, 15A, 15B, 16A, 16B, 17A, 17B, 17C, 17D, 17E, 17F, 17G, 17H, 17I, 17J, 17K, 17L, 17M, 17N, 17O and 17P illustrate the formation of Continuous Polysilicon on Diffusion edge (CPODE) regions in accordance with some embodiments.

FIGS. 21-36 illustrate forming Cut-Metal Gate (CMG) isolation interfaces in accordance with some embodiments.

FIG. 39 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Dielectric materials can be used for device isolation in the manufacture of semiconductor devices, e.g., in the form of spacers, liners and gap fill materials. However, some dielectric materials have a high level of positive fixed charge, resulting from point defects, such as in the case of K+ centers that may be present in silicon nitride (SiN) that is deposited using plasma enhanced chemical vapor deposition (PEVD) or plasma enhanced atomic layer deposition (PEALD). A high level of positive fixed charge may cause multiple device performance issues. In some instances, a high level of positive fixed charge in materials used as the material in an isolation structure can induce an inversion layer within an adjacently positioned p-type or p-type doped well, which can lead to undesired leakage current.

The effects of induced charge from dielectric gap fill isolation structures may be mitigated by positioning a buffer layer having a lower fixed charge level material between the gap fill dielectrics having the high fixed charge level material and doped well regions, e.g., n-type and/or p-type doped wells.

In some examples, to mitigate inter-transistor leakage it can be advantageous to increase the thickness of the buffer layer having the low fixed charge level dielectric composition material within the isolation structure. However, increasing the thickness of the buffer layer positioned within a trench or opening with a conformal deposition method can simultaneously decrease a gap opening critical dimension (CD). Decreasing the gap opening for the isolation structure can lead to difficulty in depositing the dielectric gap fill that is used for filling the isolation opening or trench structures.

This methods and structures described herein can produce a thick buffer layer at the base of an opening or trench structure using a bottom-up fill process. The thickness of the buffer layer present at the base of the trench isolation structure can mitigate induced charge effects in p-type and n-type wells from the fixed charge of the isolator material within the trench structure without narrowing the opening, e.g., critical dimension (CD), to the trench isolation structure.

In the illustrated embodiments, the formation of GAA Transistors are used as an example to explain the concept of the present disclosure. Other types of transistors such as Fin Field-Effect Transistors (FinFETs), planar transistors, or the like may also adopt the concept of the present disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

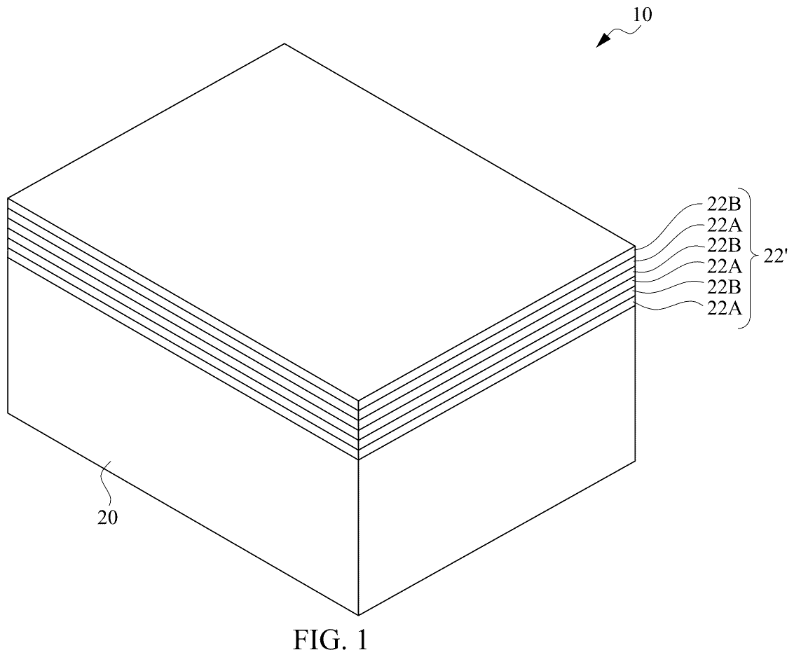

FIGS. 1-38B illustrate the views of intermediate stages in the formation of transistors in accordance with some embodiments of the present disclosure.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

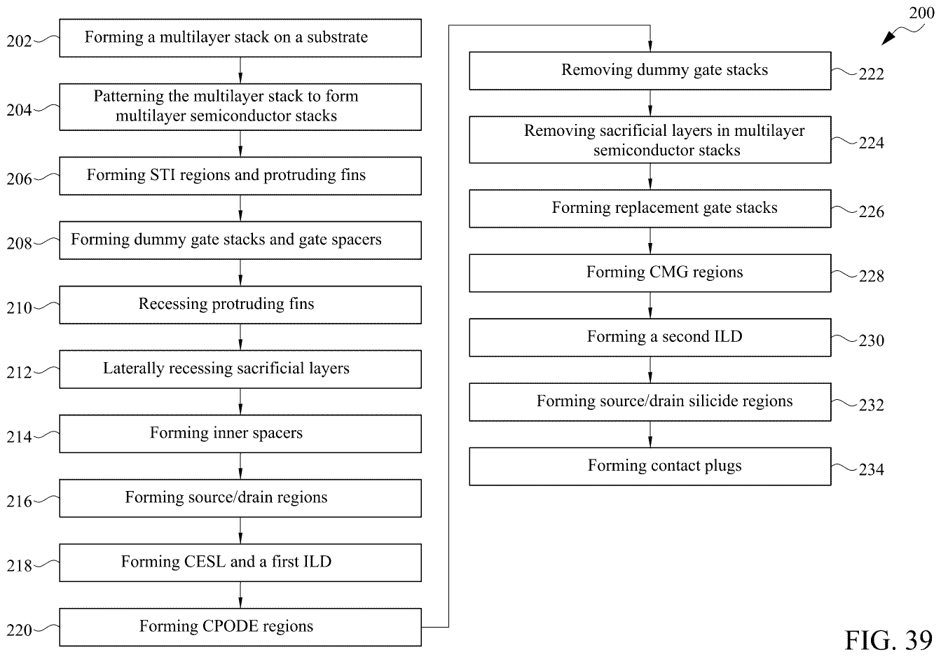

In accordance with some embodiments, multilayer stack 22 is formed through a series of deposition processes for depositing alternating materials. The respective process is illustrated as process 202 in the process flow 200 shown as in FIG. 39. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

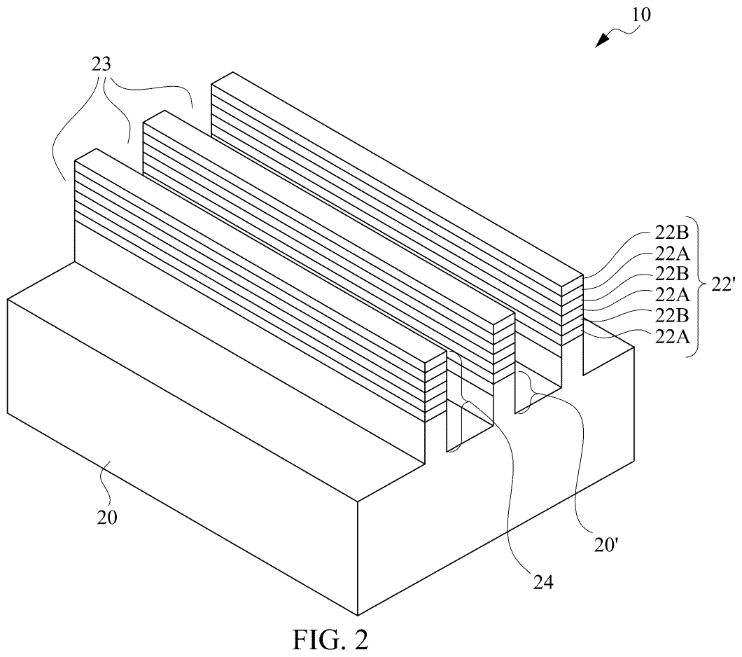

Referring to FIG. 2, multilayer stack 22 and a portion of the underlying substrate 20 are patterned in an etching process(es), so that trenches 23 are formed. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in an embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the device structure.

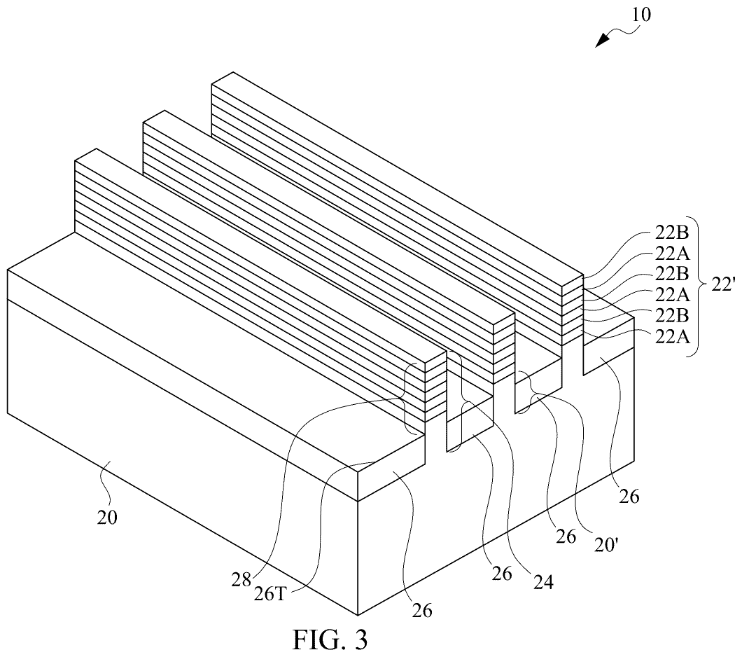

FIG. 3 illustrates the formation of isolation regions 26, which are also referred to as Shallow Trench Isolation (STI) regions throughout the description. The respective process is illustrated as process 206 in the process flow 200 shown as in FIG. 39. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF3 and NH3, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

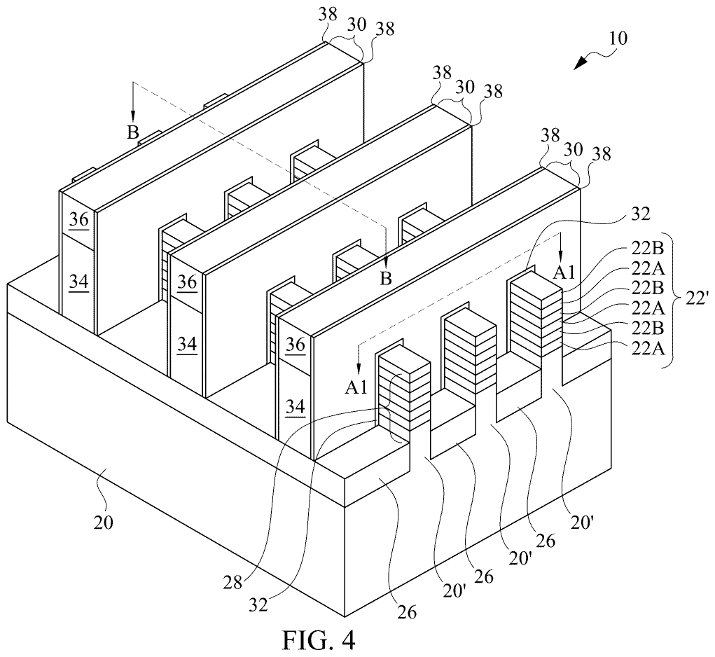

Referring to FIG. 4, dummy gate stacks 30 and gate spacers 38 are formed on the top surfaces and the sidewalls of (protruding) fins 28. The respective process is illustrated as process 208 in the process flow 200 shown as in FIG. 39. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask 36 over the dummy gate electrode 34. Hard masks 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SIN), silicon oxide (SiO), silicon carbide (SiC), silicon oxide (SiO2), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

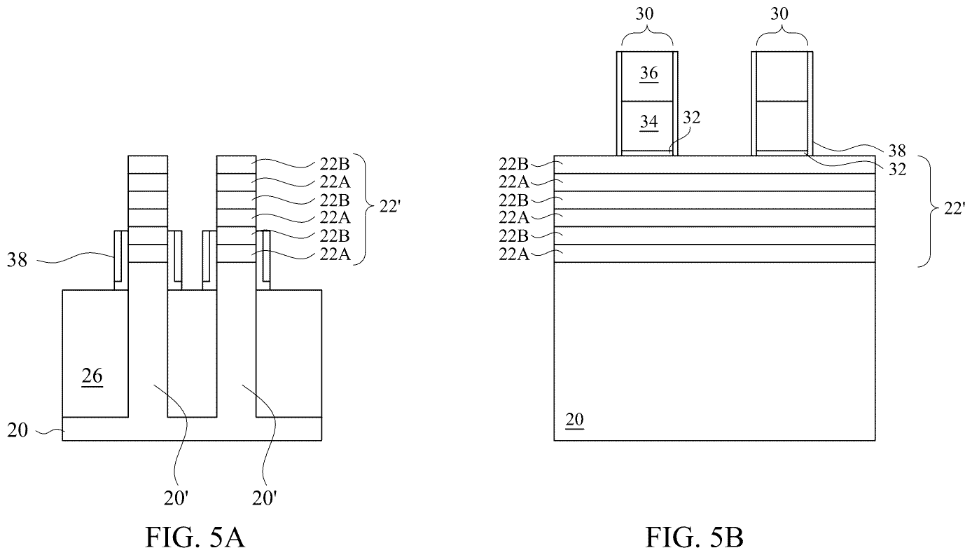

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Gate spacers 38, which are on the sidewalls of protruding fins 28, are also illustrated. FIG. 5B illustrates the reference cross-section B-B in FIG. 4, which reference cross-section is parallel to the lengthwise directions of protruding fins 28.

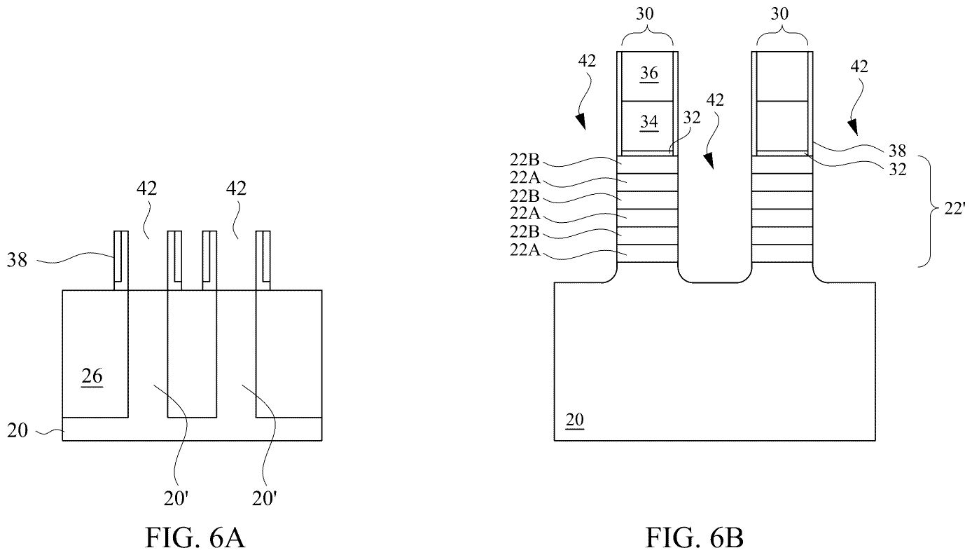

Referring to FIGS. 6A and 6B, the portions of protruding fins that are not directly underlying dummy gate stacks 30 and gate spacers 38 are recessed through an etching process to form recesses 42. The respective process is illustrated as process 210 in the process flow 200 shown as in FIG. 39. For example, a dry etch process may be performed using C2F6, CF4, SO2, the mixture of HBr, Cl2, and O2, the mixture of HBr, Cl2, O2, and CH2F2, or the like to etch multilayer semiconductor stacks 22′and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

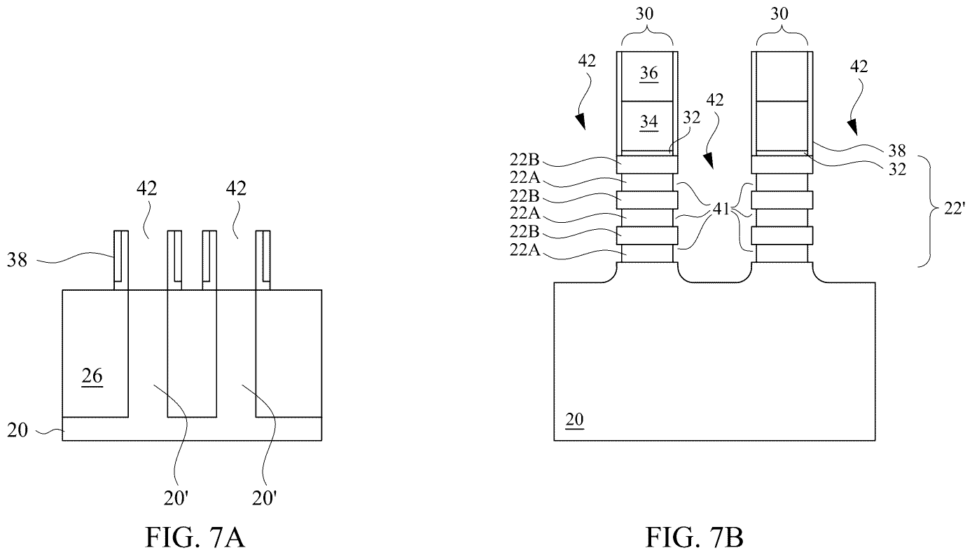

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown as in FIG. 39. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

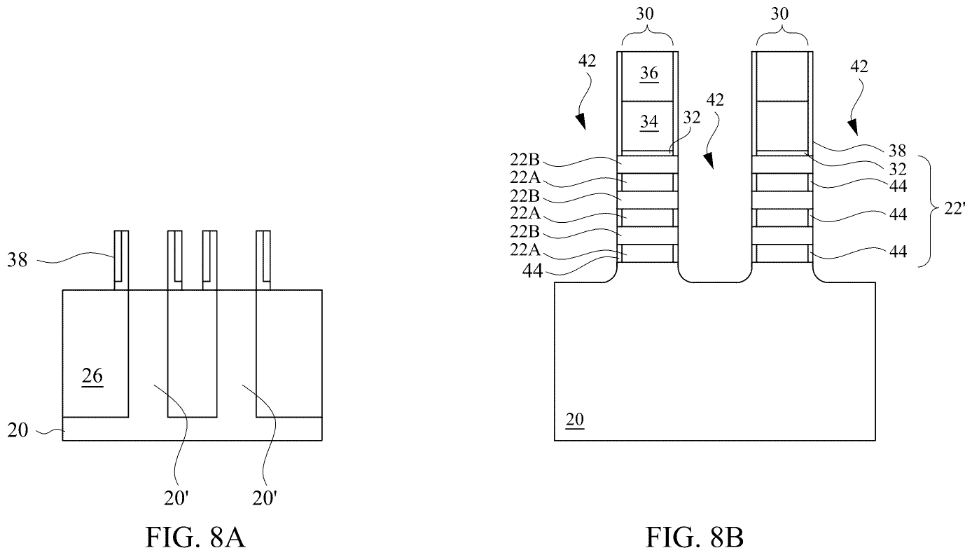

Referring to FIGS. 8A and 8B, inner spacers 44 are formed. The respective process is illustrated as process 214 in the process flow 200 shown as in FIG. 39. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

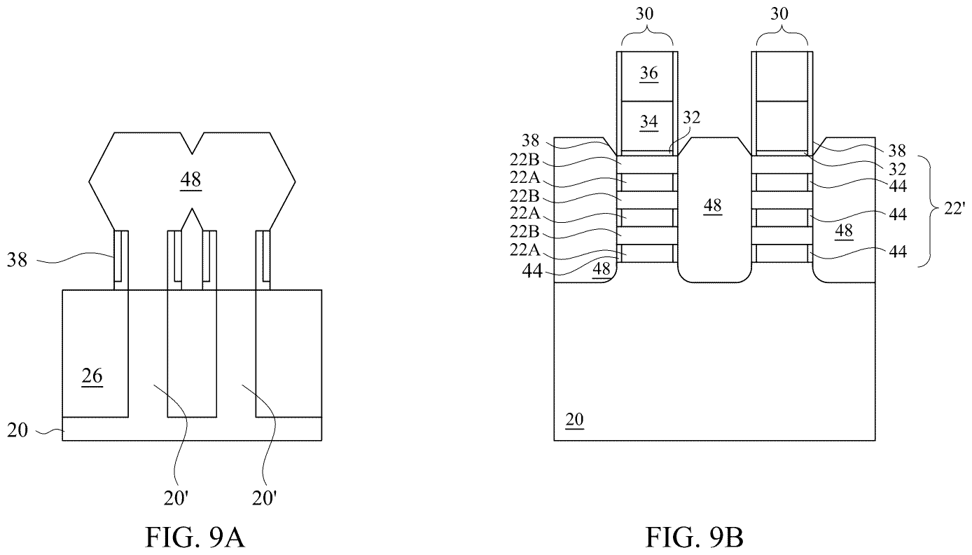

FIGS. 9A and 9B illustrate the cross-sectional views in the formation source/drain regions 48 in recesses 42 through epitaxy. The respective process is illustrated as process 216 in the process flow 200 shown as in FIG. 39. Source/drain region(s) may refer to a source or a drain, individually or collectively dependent upon the context. In accordance with some embodiments, the source/drain regions 48 may exert stress on the nanostructures 22B, which are used as the channels of the corresponding GAA transistors, thereby improving performance.

In accordance with some embodiments, the corresponding transistor is n-type, and epitaxial source/drain regions 48 are accordingly formed as n-type by doping an n-type dopant. For example, silicon phosphorous (SiP), silicon carbon phosphorous (SiCP), or the like may be grown to form epitaxial source/drain regions 48. In accordance with alternative embodiments, the corresponding transistor is p-type, and epitaxial source/drain regions 48 are accordingly formed as p-type by doping a p-type dopant. For example, silicon boron (SiB), silicon germanium boron (SiGeB), or the like may be grown to form epitaxial source/drain regions 48. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other, with voids being formed.

After the epitaxy process, epitaxy regions 48 may be further implanted with an n-type impurity or a p-type impurity to form source and drain regions, which are also denoted using reference numeral 48. In accordance with alternative embodiments of the present disclosure, the implantation process is skipped when epitaxy regions 48 are in-situ doped with the n-type impurity or p-type impurity during the epitaxy, and the epitaxy regions 48 are also source/drain regions.

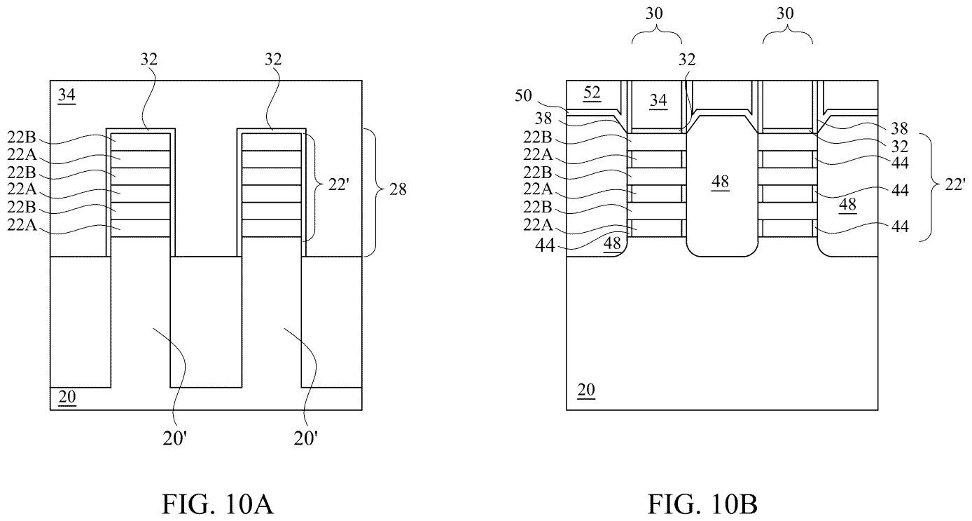

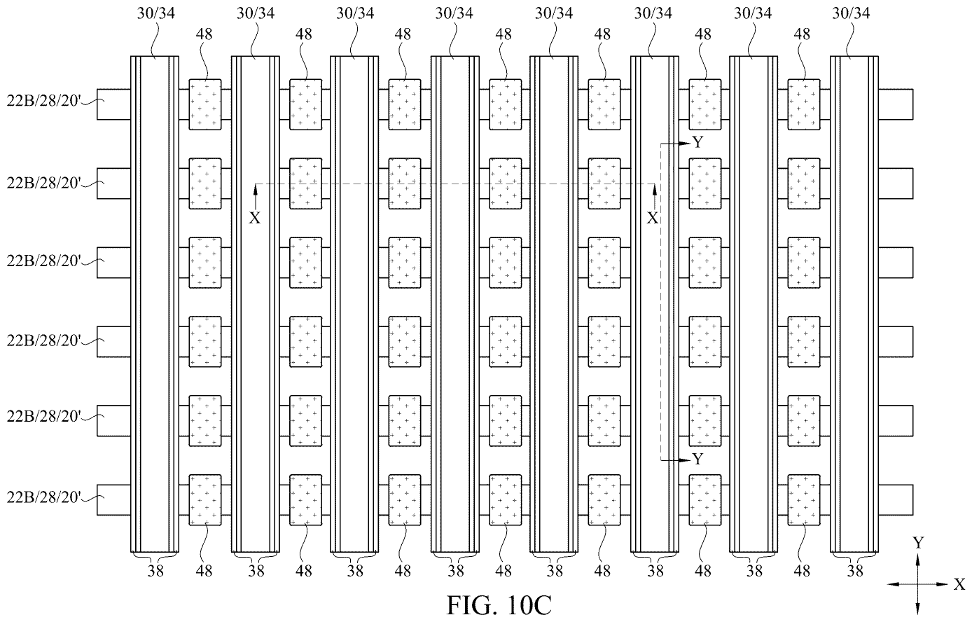

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown as in FIG. 39. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

FIG. 10C illustrates a top view of the structure shown in FIGS. 10A and 10B in accordance with some embodiments. Multilayer stacks 22′, substrate strips 20′, and protruding fins 28 (refer to FIG. 10A) have lengthwise directions in the X-direction, and the corresponding cross-sectional view is referred to as the X-cut view. Gate stacks 30, which includes dummy gate electrodes 34 (such as polysilicon strips) have lengthwise directions in the Y-direction, and the corresponding cross-sectional view is referred to as the Y-cut view. Source/drain regions 48 are formed based on some portions of the multilayer stacks 22′ (as viewed in FIGS. 5B and 10B). The edges of source/drain regions may be in contact with, or may be spaced apart from, gate spacers 38.

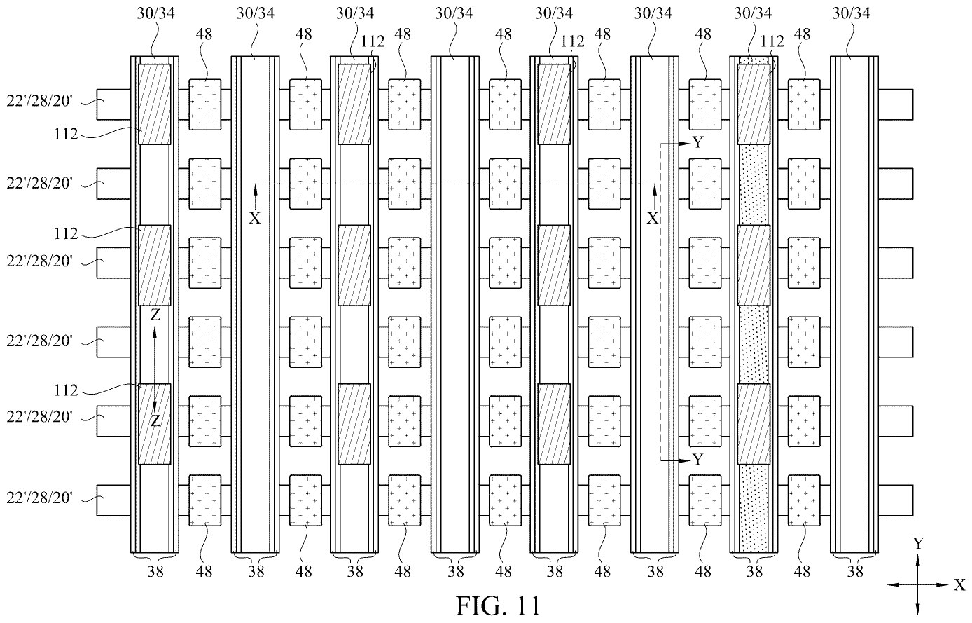

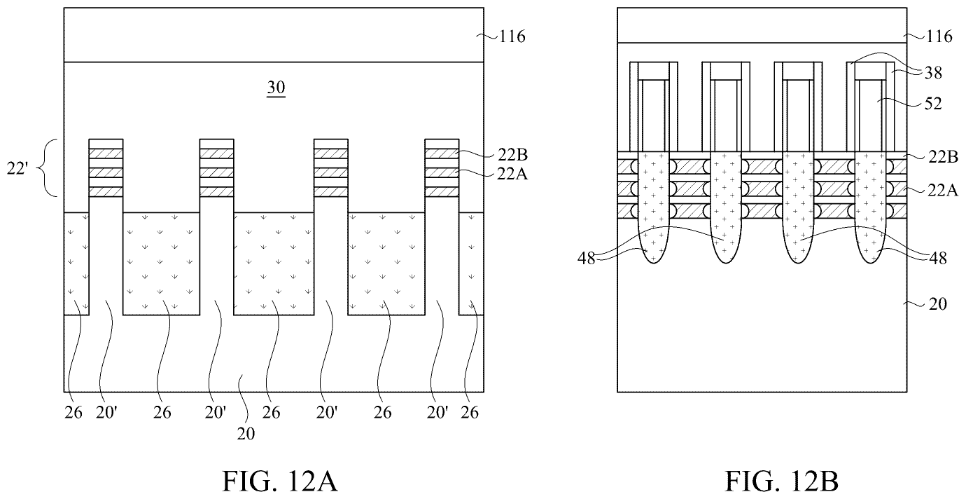

FIG. 11 illustrates the top view of the formation of fin isolation regions 112. In accordance with some embodiments, as shown in FIG. 11, fin isolation regions 112 are Continuous Polysilicon on Diffusion edge (CPODE) regions, whose formation involves etching dummy gate stacks 30, multilayer stacks 22′, and substrate strips 20′. The respective process is also illustrated as process 220 in the process flow 200 shown as in FIG. 39. The detailed process for forming fin isolation regions 112 by cutting dummy gate stacks 30 are shown in FIGS. 12A through 17P.

FIGS. 12A-17P illustrate the formation of fin isolation regions 112 (using CPODE processes) in accordance with some embodiments. In subsequent figures, the figures having letter A following the corresponding figure numbers are obtained from the Y-cut (along Y-direction) in FIG. 11, while the figures having letter B following the corresponding figure numbers are obtained from the X-cut (along X-direction) in FIG. 11.

FIGS. 12A and 12B illustrate the structure in FIG. 10C, and are obtained from the cross-sections Y-cut and X-Cut, respectively. FIGS. 12A and 12B also correspond to FIGS. 10A and 10B, respectively. Accordingly, FIG. 12A illustrates multi-layer stacks 22′, and dummy gate stack 30 on multi-layer stacks 22′. FIG. 12B illustrates source/drain regions 48, multi-layer stacks 22′, inner spacers 44, and dummy gate stacks 30.

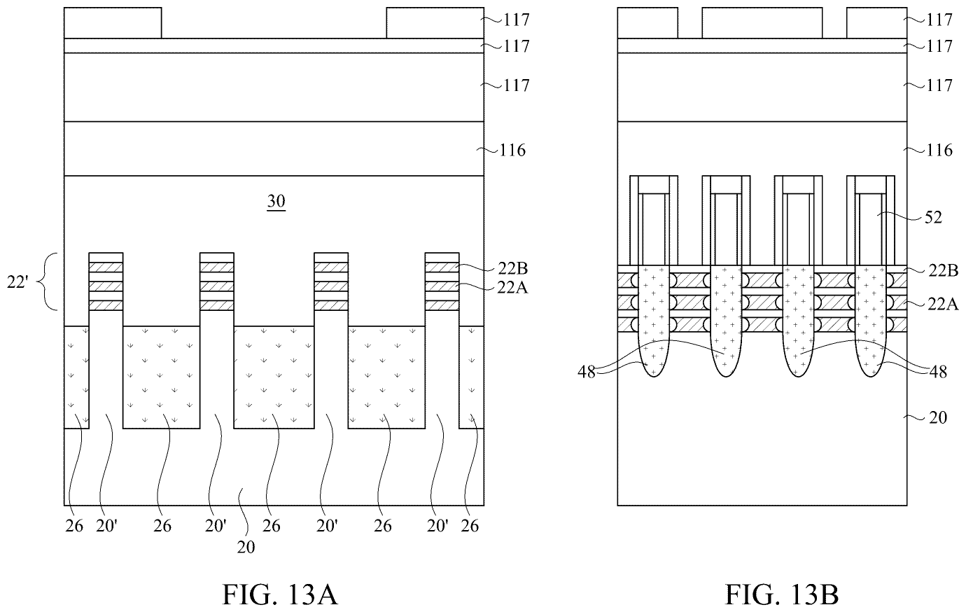

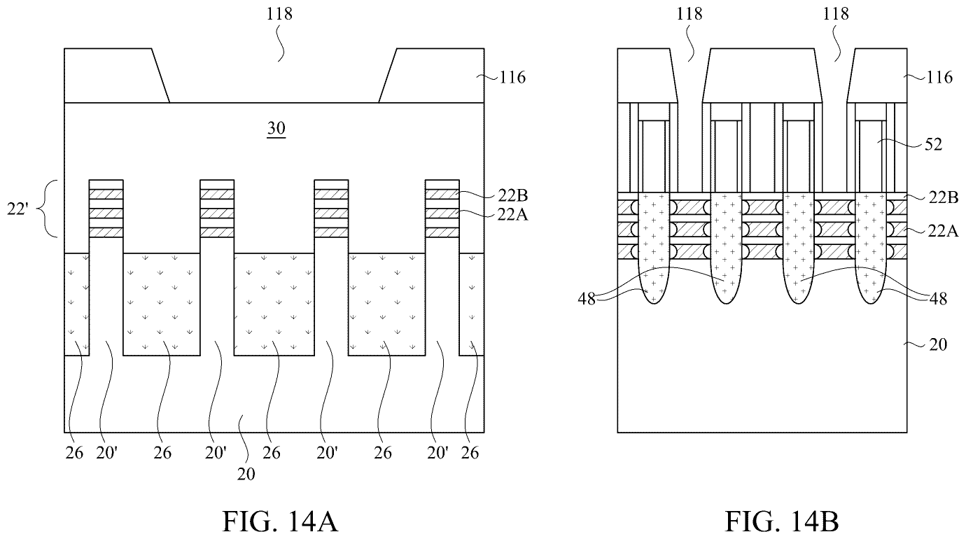

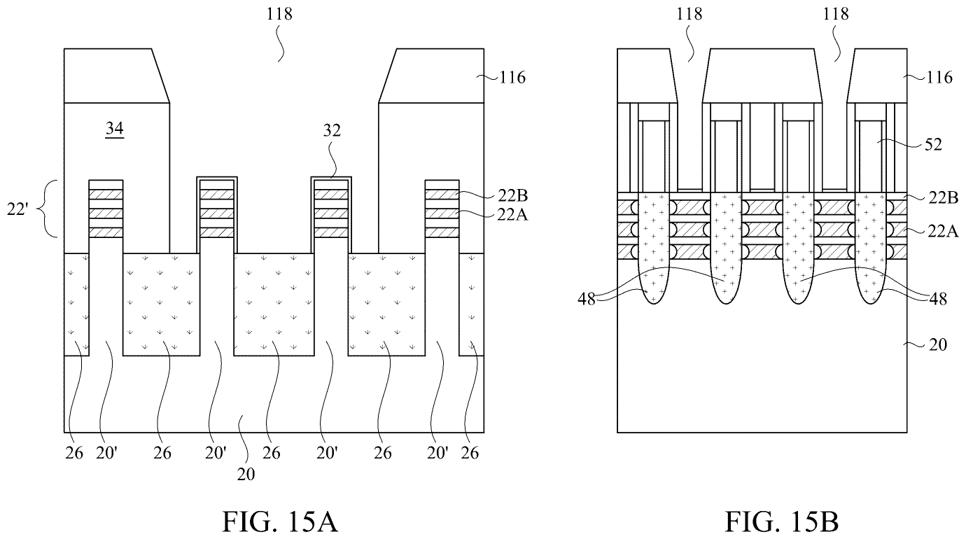

Referring to FIGS. 12A and 12B, hard mask 116 is formed. Hard mask 116 may comprise a dielectric material such as SiN, silicon, or the like, or multi-layers thereof. Etching mask 117 (e.g., a tri-layer photoresist), which is patterned, is formed over hard mask 116. Next, as shown in FIGS. 13A-14B, hard mask 116 is etched to form openings 118, through which dummy gate electrode of the dummy gate stacks 30 is exposed. Hard mask 116 is then used to etch-through the underlying dummy gate electrode of the dummy gate stacks 30, until dummy gate dielectric 32 is exposed, as shown in FIGS. 15A and 15B. The etching is anisotropic, so that the edges of the dummy gate electrode facing opening 118 are vertical and straight. In the etching process, dummy gate dielectric 32 may be used as an etch stop layer.

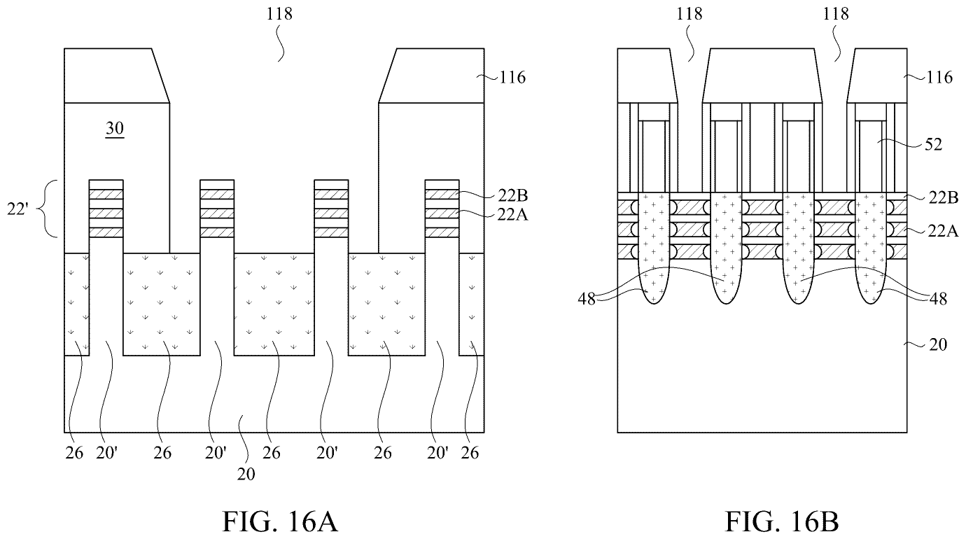

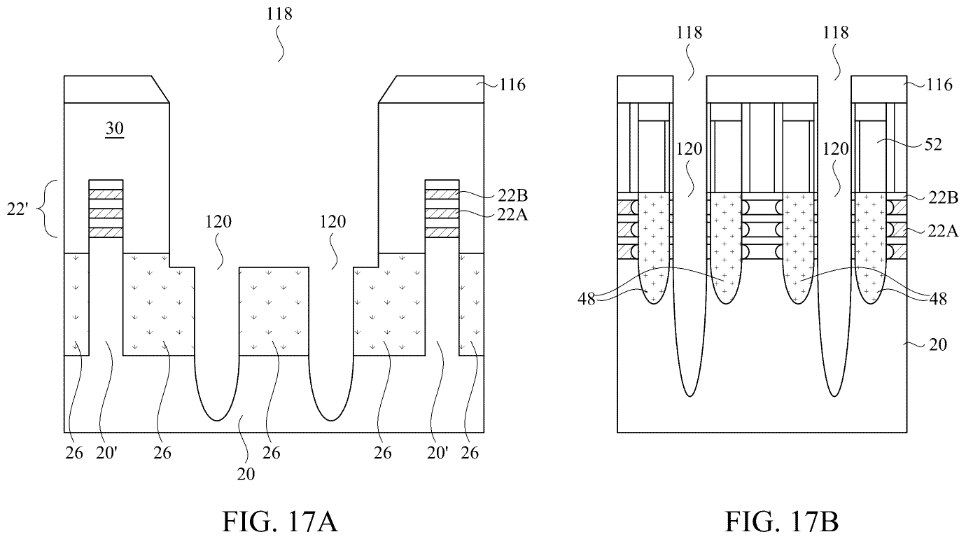

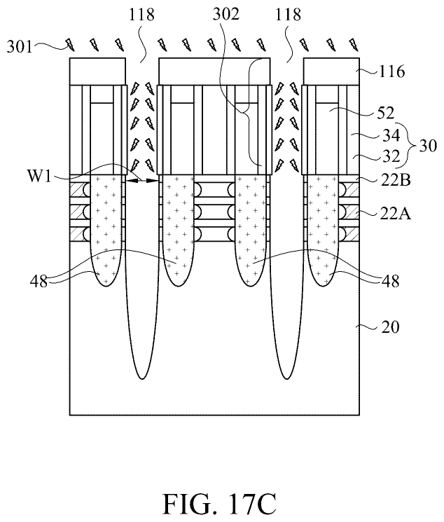

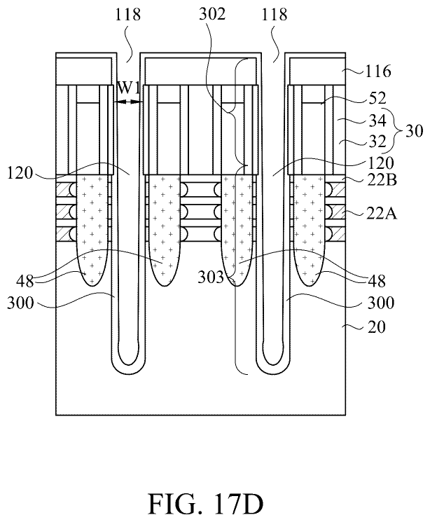

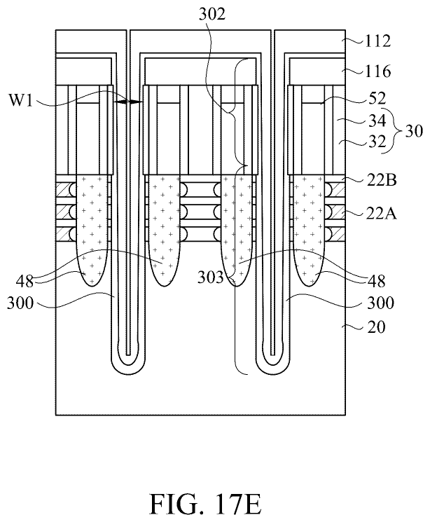

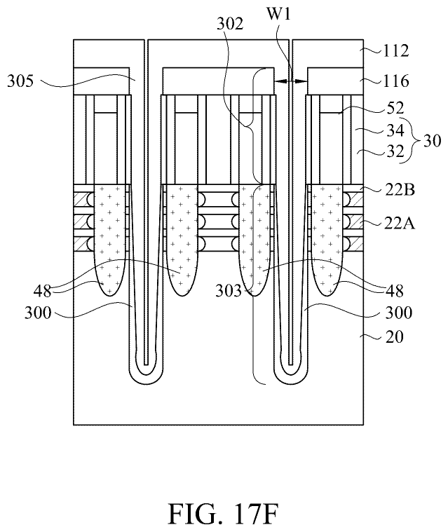

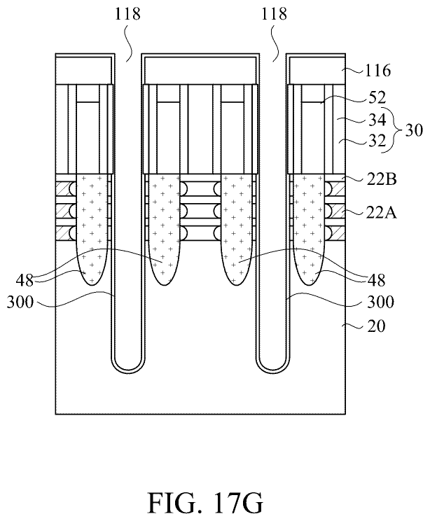

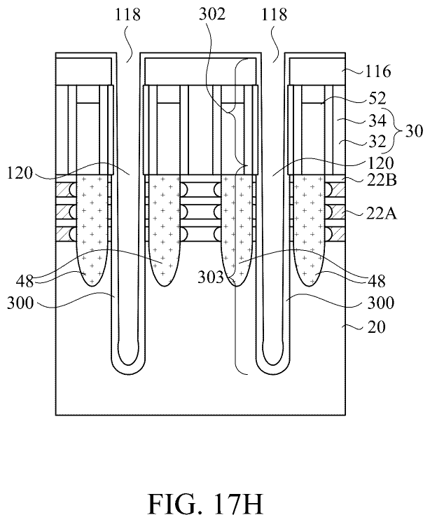

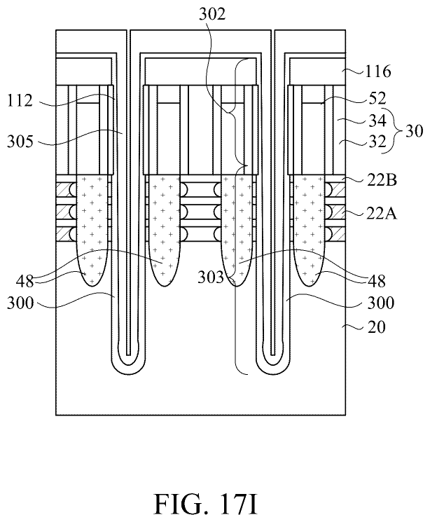

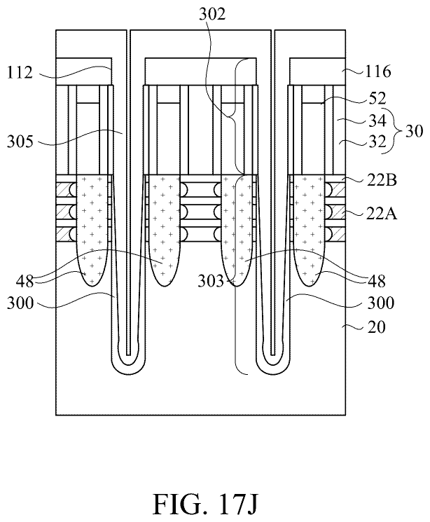

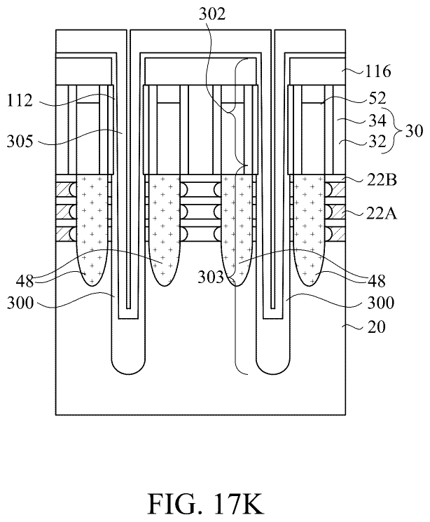

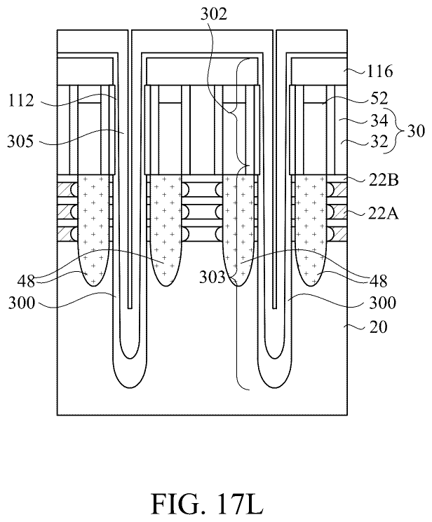

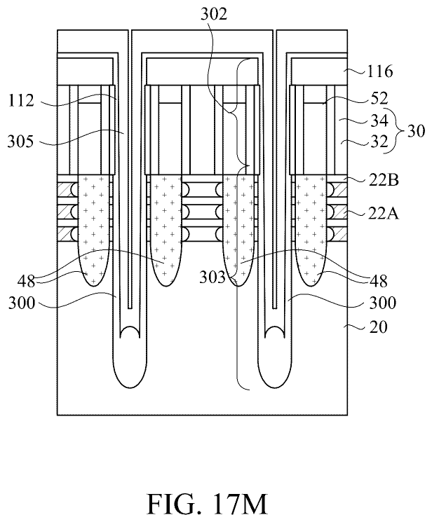

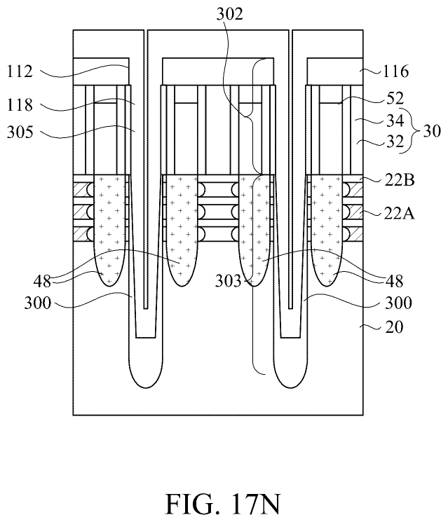

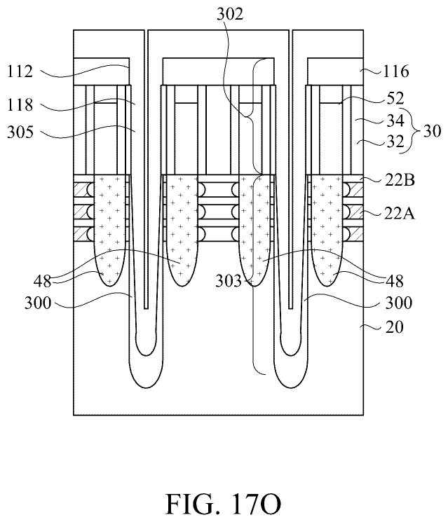

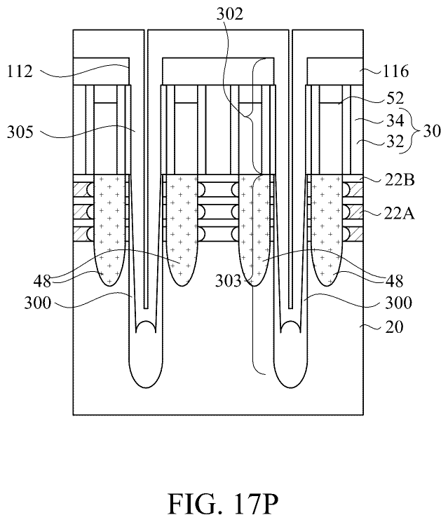

Dummy gate dielectric 32 is then removed, for example, through an isotropic etching process, so that multi-layer stacks 22′ are revealed. The resulting structure is shown in FIGS. 16A and 16B. Next, an etching process(es) is performed to remove the exposed multi-layer stacks 22′, followed by the further etching of the underlying semiconductor material such as substrate strips 20′. Openings 120 are thus formed between neighboring STI regions 26, as shown in FIGS. 17A and 17B. Openings 120 may extend to a level lower than the bottom surfaces of STI regions 26 to reduce leakage. In some embodiments, the openings 120 may extend into regions of the substrate 20 including well regions of n-type and/or p-type dopant.

FIGS. 17C-17E illustrate embodiments of a method for forming a buffer layer 300 within the openings 118 to mitigate induced charge in the well that is present in the substrate 20 from fixed charge of an isolating material without narrowing the width W1 of the opening 118, e.g., without narrowing the critical dimension (CD) of the opening 118. The well within the substrate 20 is n-type or p-type doped regions, which may surround the base and sidewalls of the opening 118. To avoid narrowing of the width W1 of the opening 118, the methods and structures described with reference to FIGS. 17C-17E employ a bottom up deposition approach including an inhibition treatment (passivation) that forms a greater amount of material for the buffer layer 300 in the bottom of the opening 118 than the amount of material for the buffer layer 300 in the top of the opening 118. This reduces the incidence of pinch off for the opening 118.

FIG. 17C illustrates an inhibition treatment 301 that can be a stage of a cyclic set of inhibition and deposition steps, which together can provide a dense thick buffer layer 300 (shown in FIG. 17D) at the base of the opening 118 while limiting growth of the buffer layer 300 at the upper portion 302 of the opening 118. In some embodiments, the inhibition treatment 301 may include at least one passivation treatment or a thermal treatment that is applied to an upper portion 302 of the opening 118. In some embodiments, when the inhibition treatment 301 is a thermal treatment, the thermal treatment may include a temperature ranging from around 600° C. in an inert gas atmosphere that includes hydrogen, helium, nitrogen or combinations thereof, wherein the thermal treatment includes a pressure ranging from 10 Torr to 5 ATM. In some embodiments, when the inhibition treatment 301 is a plasma treatment, the plasma treatment may include a plasma of argon, helium, hydrogen, or combinations thereof. In some embodiments, the temperature for the plasma treatment ranges from 300° C. to 500° C. In some embodiments, the plasma treatment includes a pressure ranging from 10 Torr to 5 ATM. The plasma processes for the inhibition treatment 301 may be in situ and/or ex situ. An in situ process can employ the same tool for the inhibition treatment 301 as the subsequent deposition steps using plasma enhanced chemical vapor deposition (PECVD) and/or plasma enhanced atomic layer deposition (PEALD). The ex situ process employs a different tool for the inhibition treatment 301 as the subsequent deposition steps using plasma enhanced chemical vapor deposition (PECVD) and/or plasma enhanced atomic layer deposition (PEALD).

The process conditions for the inhibition treatment 301 is selected to provide that only the upper portion 302 of the opening 118 is treated. For example, the inhibition treatment 301 may be applied to only the upper half of the depth for the opening 118. In some embodiments, by controlling the pressure of the inhibition treatment 301 to range from 10 Torr to 5 ATM, the diffusion path for the deposited species of the inhibation treatment can be limited. For example, the process conditions of the inhibition treatment 301 are selected to control the diffusion path of the gas or plasma species to only treat the upper portion 302 of the opening 118. For example, the diffusion path of the gas or plasma species for the inhibition treatment may be controlled to be limited to be within the range of 5 nm to 5 microns. In some embodiments, the gas species or plasma species reacts with the sidewalls of the opening 118, such as the interlevel dielectric (ILD) 52, and removes the hydroxyl group (OH), which inhibits deposition of dielectric materials, such as the material of the buffer layer 300, onto the sidewalls of the opening 118. Following the inhibition treatment 301, the exposed sidewalls of the opening 118 through the interlevel dielectric layer (ILD) 52 have a high concentration of silicon to hydrogen (Si—H) bonds, silicon to oxygen (Si—O) bonds, and silicon to silicon (Si—Si bonds) after removing the hydroxyl (—OH) groups.

FIG. 17D illustrates an embodiment of the deposition step that can be a stage of a cyclic set of inhibition and deposition steps that together can provide a dense thick buffer layer 300 at the base of the opening 118 while limiting growth of the buffer layer 300 at the upper portion 302 of the opening 118. In some embodiments, forming the buffer layer 300 includes forming a non-conformal material layer having a lower fixed charge concentration than silicon nitride, e.g., Si3N4, wherein the non-conformal material layer has a first portion on the upper portion 302 of the opening 118 passivated by the at least one passivation treatment, and the non-conformal layer has a second portion that extends into the lower portion 303 of the opening 118 that includes the base of the opening 118. In some embodiments, the first portion of the non-conformal material layer that provides the buffer layer 300 in the upper portion 302 of the opening 118 has a lesser thickness than the second portion of the non-conformal material layer that provides the buffer layer 300 in the lower portion 303 of the opening 118. When compared to the thickness of the buffer layer 300 in the upper portion 302 of the opening 118, the greater thickness of the buffer layer 300 in the lower portion 303 of the opening 118 provides a greater amount of dielectric film with a lower fixed charge level between gap fill dielectrics (depicted in FIG. 17E) with a high fixed charge level and doped well regions, e.g., n-type and/or p-type doped well, that are present in the substrate 20. The lesser thickness of the buffer layer 300 in the upper portion 302 of the opening 118 does not significantly reduce the width W1 of the opening 118 in a manner that would restrict dielectric fill deposition processes for filling the opening 118 with isolator material (as illustrated in FIG. 17E). A low fixed charge level dielectric is a material used as an insulator that has a minimal amount of trapped electrical charges (fixed charges) within its structure. By minimizing fixed charge, the low fixed charge level dielectric can minimize unwanted electrical effects like leakage current. Examples of low fixed charge level dielectrics for the buffer layer 300 can include silicon oxide (SiO2), silicon carbon oxide (SiCO), silicon carbon nitride (SiCN) and/or silicon carbon oxynitride (SiCON). An example of a fill dielectric having a high fixed charge level is silicon nitride (SiN).

The buffer layer 300 may be deposited using plasma enhanced chemical vapor deposition (PECVD), atomic layer deposition (ALD), plasma enhanced atomic layer deposition (PEALD) or a combination thereof. The inhibition treatment 301 that reduces the concentration of hydroxyl (—OH) groups in the upper portion 302 of the opening 118 reduces the reactivity of the sidewall of the opening 118 for deposition of the buffer layer 300 in the upper portion of the opening 118. The reduction in reactivity causes the thickness of the buffer layer 300 that is deposited in the upper portion 302 of the opening 118 to be less than the thickness of the buffer layer 300 in the lower portion 303 of the opening 118. The lower portion 303 of the opening 118 has a greater reactivity with the deposited species, because the diffusion path for the inhibition treatment 301 is short to avoid the inhibition treatment 301 reaching the lower portion 303 of the opening 118. In some embodiments, the difference in the thickness between the first portion of the non-conformal material layer for the buffer layer 300 in the upper portion 302 of the opening 118, and the second portion of the non-conformal layer for the buffer layer 300 in the lower portion 303 of the opening 118 ranges from 2 nm to 10 nm. In one example, the difference in the thickness between the first portion of the non-conformal material layer for the buffer layer 300 in the upper portion 302 of the opening 118, and the second portion of the non-conformal layer for the buffer layer 300 in the lower portion 303 of the opening 118 may range from 2 nm to 5 nm. In some examples, the difference in the thickness of the buffer layer 300 from the upper portion 302 of the opening 118 to the lower portion 303 of the opening 118 may be gradual.

It is noted that the inhibition step depicted in FIG. 17C and the deposition step depicted in FIG. 17D are stages of a cycle that may be repeated to provide a bottom up fill for the opening 188 with the non-conformal material layer having a lower fixed charge concentration than silicon nitride. For example, the cycle of the inhibition step depicted in FIG. 17C and the deposition step depicted in FIG. 17D may be repeated 2 times to 100 times. However, the number of repetitions for the cycle of the inhibition step and the deposition step may be repeated any number of times to provide the appropriate amount of material for the buffer layer 300 in the base of the opening 118.

FIG. 17E illustrates an embodiment of depositing a fill dielectric 305 on the non-conformal material layer that provides the buffer layer 300. The fill dielectric 305 may be composed of an etch resistant material. For example, the fill dielectric 305 may be composed of silicon nitride, e.g., Si3N4. The fill dielectric 305 composed of silicon nitride can be a high fixed charge level isolator (dielectric material). The fill dielectric 305 may be deposited using chemical vapor deposition (CVD), plasma enhanced chemical vapor deposition (PECVD), atomic layer deposition (ALD), plasma enhanced atomic layer deposition (PEALD) and combinations thereof. It is noted that in some embodiments, the fill dielectric 305 is directly atop the buffer layer 300 and completely fills the opening 118.

FIGS. 17A-117E illustrate an embodiment of filling of openings 118 and 120 to form CPODE isolation region 112. A planarization process such as a chemical mechanical planarization (CMP) process may then be performed to form fin isolation region 112, which is a CPODE isolation region, which is also shown in FIG. 11.

FIG. 17F illustrates another embodiment in which the inhibition step depicted in FIG. 17C may be adjusted to tune the thickness of the buffer layer 300 on the sidewalls and the base of the opening 118. For example, the pressure and/or the time period of the inhibition step depicted in FIG. 17C may be increased to increase the removal of the hydroxide groups (-OH) from the upper portion 302 of the opening 118. By increasing the aggressiveness of the inhibition step, a lesser degree of buffer layer 300 may be deposited in the upper portion 302 of the opening 118. In the example depicted in FIG. 17F, the buffer layer 300 is not present in the upper portion 302 of the opening 118, and is entirely present in the lower portion 303 of the opening 118 that includes the base. In some embodiments, a top surface of the buffer layer 300 is lower than the top surface of the source/drain 48.

FIGS. 17G-17I illustrate another embodiment of a method for forming a buffer layer 300 within the openings 118 to mitigate induced charge in the well that is present in the substrate 20 from fixed charge of an isolating material without narrowing the width W1 of the opening 118, e.g., without narrowing the critical dimension (CD) of the opening 118. To avoid narrowing of the width W1 of the opening 118, the methods and structures described with reference to FIGS. 17G-17I employ a bottom up deposition approach including a cyclic deposition step and recess etching step that forms a greater amount of material for the buffer layer 300 in the bottom of the opening 118 than the amount of material for the buffer layer 300 in the top of the opening 118. The method depicted in FIGS. 17G-17I illustrate a cyclic deposition, which can be conformal or directional, and in situ removal of the buffer layer from the top and sidewall of the opening 118. The method illustrated in FIGS. 17G-17I also reduces the incidence of pinch off for the opening 118.

FIG. 17G illustrates an embodiment of forming a buffer layer 300 of a low fixed charge dielectric within the opening 118. For example, in some embodiments, the composition for the buffer layer 300 has a lower fixed charge concentration than silicon nitride. In some examples, the buffer layer 300 may be composed of silicon oxide (SiO2), silicon oxynitride (SiON), silicon oxycarbon nitride (SiCON) or combinations thereof.

The buffer layer 300 may be deposited into the opening 118 using a directional deposition process or a conformal deposition process. In some embodiments, the directional deposition process forms a greater thickness of the material for the buffer layer on the base of the opening 118, and the upper surfaces of the interlevel dielectric layer (ILD) 52 adjacent to the opening 118, which may be referred to as horizontally orientated surfaces. The material that is deposited on the sidewalls of the opening 118 by the directional deposition process for the buffer layer 300 has a lesser thickness than the portions of the buffer layer 300 that is present at the base of the opening 118. In comparison to a directional deposition process, a conformal deposition process deposits a material for the buffer layer 300 having substantially the same thickness on the sidewalls of the opening 118 and the base of the opening 118.

The buffer layer 300 may be deposited into the opening 118 using plasma enhanced chemical vapor deposition (PECVD), atomic layer deposition (ALD), plasma enhanced atomic layer deposition (PEALD) or combinations thereof. In some embodiments, to adjust the deposition process to provide a directional deposition for the buffer layer 300, the pressure of the deposition process may be set to provide a low pressure of 1 Torr or less.

FIG. 17H illustrates an embodiment of etching the buffer layer 300 to produce a non-conformal thickness, wherein the non-conformal thickness of the buffer layer 300 includes a first portion in an upper portion 302 of the opening 118 having a lesser thickness than a second portion of the buffer layer 300 in a lower portion 303 of the opening 118 including the base of the opening 118. The etch process may be a gas etch or a plasma etch. The composition of the etchant species for etching the buffer layer 300 may be a fluorine containing composition, such as hydrofluoric etchant (HF). The etching process conditions may be selected to provide that the etchant removes a greater amount of material from the upper portion 302 of the opening 118 than the lower portion 303 of the opening 118. For example, the non-conformal characteristics for the etched buffer layer 300 may include a thick portion of the material for the buffer layer 300 at the base of the opening 118, and a greatest sidewall thickness for the etched buffer layer 300 towards the base of the opening 118. The sidewall thickness for the buffer layer 300 may decrease in the direction from the base of the opening 118 towards the upper surface of the opening 118. The change in thickness of the material for the buffer layer 300 may be gradual.

For example, when the etch process is a plasma etch, the etch conditions to provide the non-conformal thickness of the buffer layer 300 may include a pressure ranging from 10 Torr to 30 Torr, a temperature ranging from 300° C. to 500° C., and plasma having a greater ratio of radicals to ions. In some embodiments, to provide that the plasma etch removes more material for the buffer layer 300 from the upper portion 302 of the opening 118 without removing (or significantly removing) the material of the buffer layer 300 from the lower portion 303 of the opening 118, the plasma may be adjusted to provide a greater concentration of radicals than ions. The diffusion path for ions is greater than the diffusion path for radicals. By minimizing the ion concentration the diffusion path for the etchant can be limited. In some examples, the radical to ion ratio for the plasma etchant may range from 1,000:1 to 100,000:1.

In some embodiments, the etch process causes the thickness of the buffer layer 300 that is present in the upper portion 302 of the opening 118 to be reduced to be less than the thickness of the buffer layer 300 in the lower portion 303 of the opening 118. In some embodiments, the difference in the thickness between the first portion of the non-conformal material layer for the buffer layer 300 in the upper portion 302 of the opening 118, and the second portion of the non-conformal layer for the buffer layer 300 in the lower portion 303 of the opening 118 ranges from 2 nm to 10 nm. In one example, the difference in the thickness between the first portion of the non-conformal material layer for the buffer layer 300 in the upper portion 302 of the opening 118, and the second portion of the non-conformal layer for the buffer layer 300 in the lower portion 303 of the opening 118 may range from 2 nm to 5 nm.

It is noted that the deposition step depicted in FIG. 17G and the etch step depicted in FIG. 17I are stages of a cycle that may be repeated to provide a bottom up fill of a non-conformal material layer having a lower fixed charge concentration than silicon nitride. For example, the cycle of the deposition step depicted in FIG. 17G and the etch step depicted in FIG. 17H may be repeated 2 times to 100 times. However, the number of repetitions for the cycle of the deposition step and the etch step may be repeated any number of times to provide the appropriate amount of material for the buffer layer 300 in the base of the opening 118.

FIG. 17I illustrates an embodiment of depositing a fill dielectric 305 on the non-conformal material layer that provides the buffer layer 300. The fill dielectric 305 may be composed of an etch resistant material. For example, the fill dielectric 305 may be composed of silicon nitride, e.g., Si3N4. The fill dielectric 305 composed of silicon nitride can be a high fixed charge level isolator (dielectric material). The fill dielectric 305 may be deposited using chemical vapor deposition (CVD), plasma enhanced chemical vapor deposition (PECVD), atomic layer deposition (ALD), plasma enhanced atomic layer deposition (PEALD) and combinations thereof. It is noted that in some embodiments, the fill dielectric 305 is directly atop the buffer layer 300 and completely fills the opening 118.

FIGS. 17G-17I illustrate an embodiment of filling of openings 118 and 120 to form a fin isolation region 112 (also referred to as CPODE isolation region 112). A planarization process such as a chemical mechanical planarization (CMP) process may then be performed to form fin isolation region, which is a fin isolation region 112 (also referred to as CPODE isolation region 112), which is also shown in FIG. 11.

FIG. 17J illustrates another embodiment of the present disclosure forms a buffer layer 300 using a deposition step as described above with reference to FIG. 17G in combination with an etch step that is similar to the etch process that is described with reference to FIG. 17H with adjustments in the etch process that result in more aggressive material removal from the upper portion 302 of the opening 118. In FIG. 17J, the buffer layer 300 has been removed from an entirety of the upper portion 302 of the opening 118. For example, etch time, etch temperature or pressure during the etch process may be adjusted to increase the aggressiveness of the etchant to remove material.

FIG. 17K-17M illustrate some embodiments in which the buffer layer 300 is formed by the combination of a directional deposition process, as described above with reference to FIG. 17G, and an etch process, as described above with reference to FIG. 17H. The directional deposition process deposits a greater amount, e.g., thicker thickness, of the material for the buffer layer 300 in the base of the lower portion 303 of the opening 118 when compared to a conformal deposition process.

FIG. 17K illustrates an embodiment of a buffer layer 300 that is formed by the combination of a directional deposition process, as described above with reference to FIG. 17G, and an etch process, as described above with reference to FIG. 17H. The directional deposition process for forming the buffer layer 300 depicted in FIG. 17K produces a greater thickness for the buffer layer 300 in the lower portion 303 of the opening 118 when compared to the thickness for the buffer layer 300 in the upper portion 302 of the opening 118. The portion of the buffer layer 300 at the base of the lower portion 303 of the opening 118 has a flat upper surface. The flat upper surface can be formed by adjusting the deposition conditions of the directional deposition process for forming the buffer layer 300.

FIG. 17L illustrates an embodiment of a buffer layer 300 that is formed by the combination of a directional deposition process, as described above with reference to FIG. 17G, and an etch process, as described above with reference to FIG. 17H. The directional deposition process for forming the buffer layer 300 depicted in FIG. 17K produces a greater thickness for the buffer layer 300 in the lower portion 303 of the opening 118 when compared to the thickness for the buffer layer 300 in the upper portion 302 of the opening 118. The portion of the buffer layer 300 at the base of the lower portion 303 of the opening 118 has a convex upper surface. The convex upper surface can be formed by adjusting the deposition conditions of the directional deposition process for forming the buffer layer 300.

FIG. 17M illustrates an embodiment of a buffer layer 300 that is formed by the combination of a directional deposition process, as described above with reference to FIG. 17G, and an etch process, as described above with reference to FIG. 17H. The directional deposition process for forming the buffer layer 300 depicted in FIG. 17M produces a greater thickness for the buffer layer 300 in the lower portion 303 of the opening 118 when compared to the thickness for the buffer layer 300 in the upper portion 302 of the opening 118. The portion of the buffer layer 300 at the base of the lower portion 303 of the opening 118 has a concave upper surface. The concave upper surface can be formed by adjusting the deposition conditions of the directional deposition process for forming the buffer layer 300.

FIG. 17N-17P illustrate some embodiments in which the buffer layer 300 is formed by the combination of directional deposition process, as described above with reference to FIG. 17G and a more aggressive etch process, as described above with reference to FIG. 17J. FIG. 17N illustrates a buffer layer 300 that was formed by a direction deposition step, as described with reference to FIG. 17K in combination with an aggressive etch process, as described with reference to FIG. 17J. The buffer layer depicted in FIG. 17N has a buffer layer 300 that has been removed from an entirety of the upper portion 302 of the opening 118, and includes a thick portion for the buffer layer 300 in the lower portion 303 of the opening 118 having a flat upper surface.

FIG. 17O illustrates a buffer layer 300 that was formed by a direction deposition step, as described with reference to FIG. 17L in combination with an aggressive etch process, as described with reference to FIG. 17J. The buffer layer depicted in FIG. 17O has a buffer layer 300 that has been removed from an entirety of the upper portion 302 of the opening 118, and includes a thick portion for the buffer layer 300 in the lower portion 303 of the opening 118 having a convex upper surface.

FIG. 17P illustrates a buffer layer 300 that was formed by a direction deposition step, as described with reference to FIG. 17M in combination with an aggressive etch process, as described with reference to FIG. 17J. The buffer layer depicted in FIG. 17P has a buffer layer 300 that has been removed from an entirety of the upper portion 302 of the opening 118, and includes a thick portion for the buffer layer 300 in the lower portion 303 of the opening 118 having a concave upper surface.

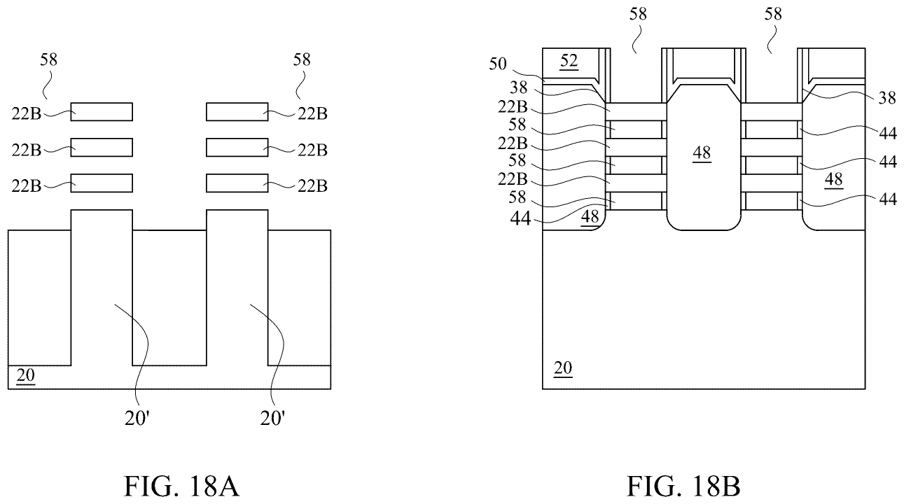

Referring to FIGS. 18A and 18B, the dummy gate electrodes 34 and dummy gate dielectrics 32 (and hard masks 36, if remaining) are removed in one or more etching processes, so that recesses 58 are formed. The respective process is illustrated as process 222 in the process flow 200 shown as in FIG. 39. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 224 in the process flow 200 shown as in FIG. 39. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH4OH), or the like may be used to remove sacrificial layers 22A.

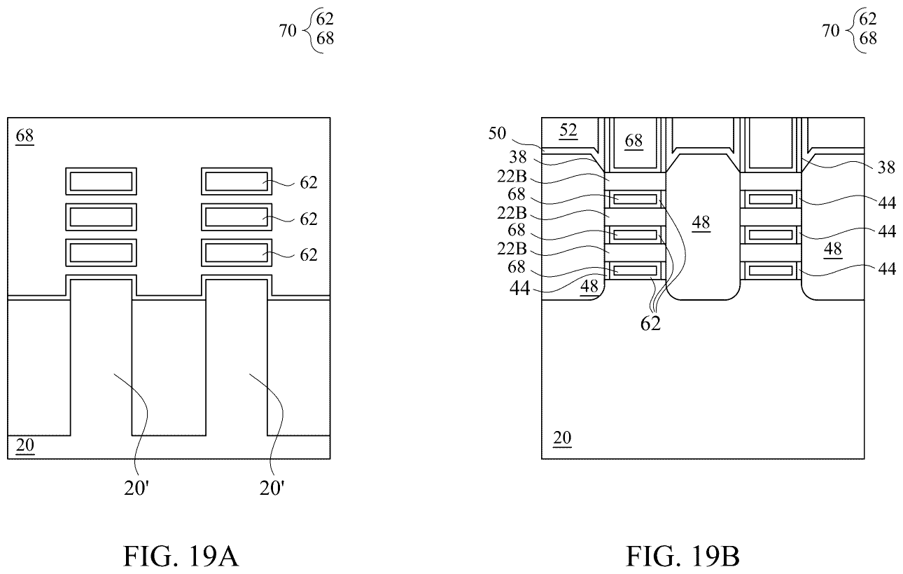

Referring to FIGS. 19A and 19B, gate dielectrics 62 and gate electrodes 68 are formed, hence forming replacement gate stacks 70. The respective process is illustrated as process 226 in the process flow 200 shown as in FIG. 39. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAIC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

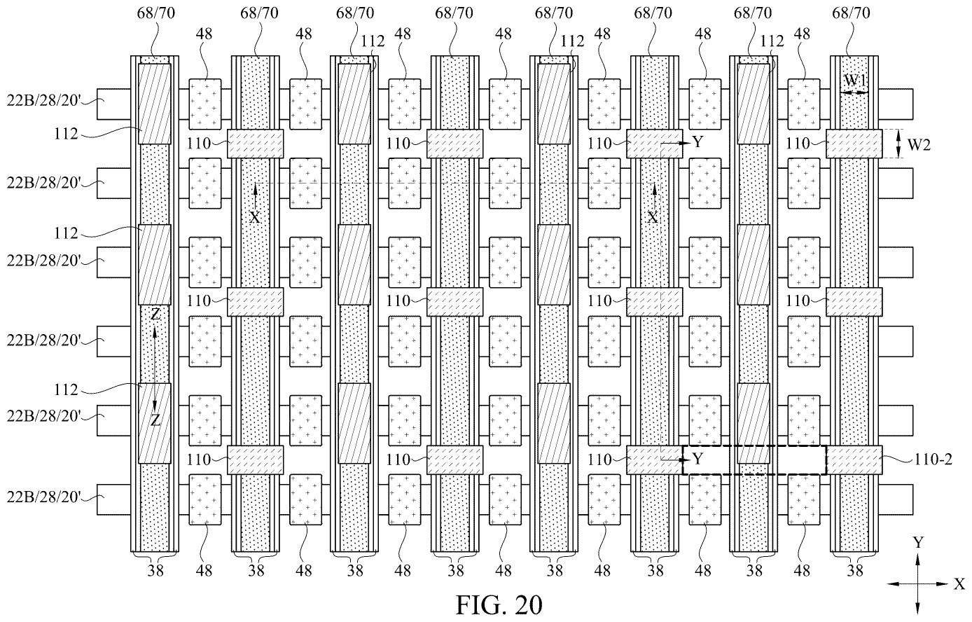

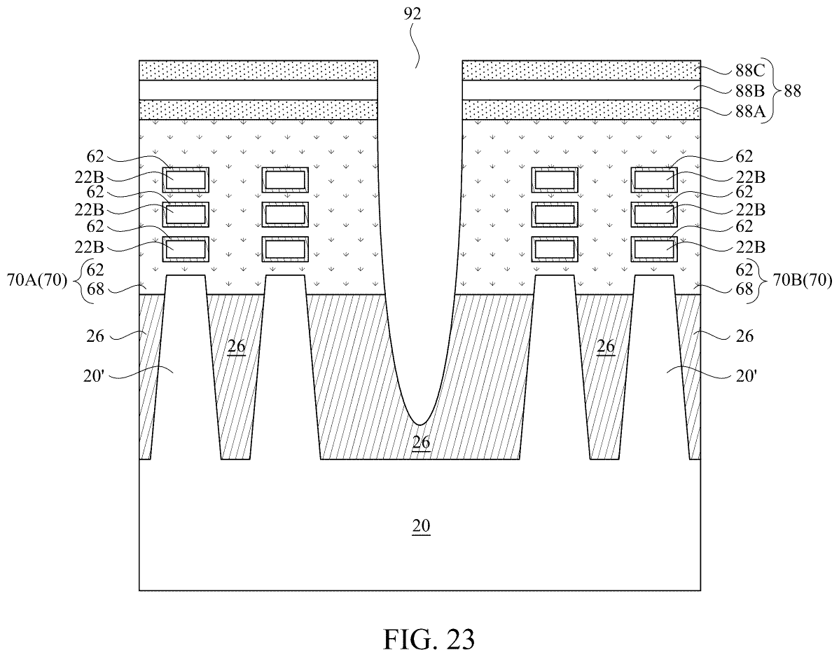

Following the formation of the gate stacks 70, Cut-Metal Gate (CMG) regions 110 may be formed, as depicted in FIGS. 20-32. FIG. 20 illustrates the top view of the formation of Cut-Metal Gate (CMG) regions 110, whose formation separates/divides the replacement (metal) gate stacks 70 into shorter portions. The respective process is illustrated as process 228 in the process flow 200 shown as in FIG. 39. CMG isolation regions 110 are also referred to as gate isolation regions 110. In accordance with some embodiments, the CMG isolation regions 110 are formed by cutting replacement gate stacks 70, as shown in FIG. 23.

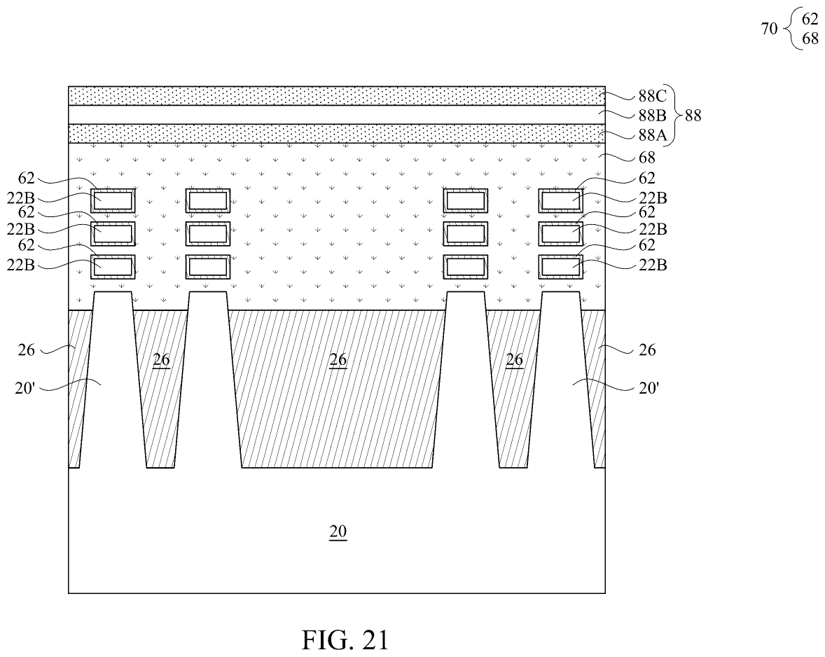

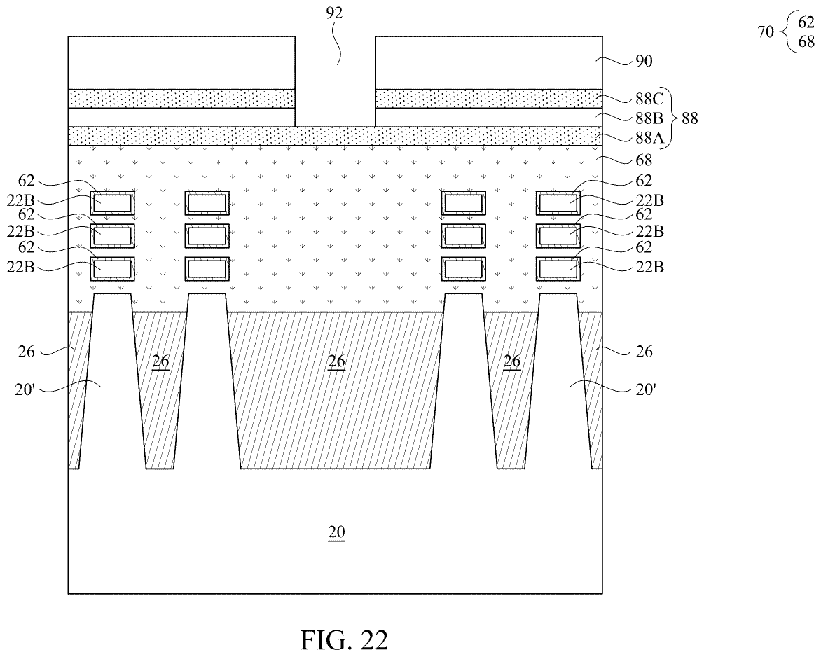

The detailed process for forming CMG isolation regions 110 may be realized from the processes shown in FIGS. 21-32. FIG. 22 illustrates a cross-sectional view of an intermediate structure, in which gate stack 70 has been formed, and includes gate dielectrics 62 and gate electrode 68, while CMG isolation region 110 has not been formed yet. In accordance with some embodiments, hard mask layer 88 is deposited, and may include a multi-layer structure including a plurality of layers. In accordance with some embodiments, hard mask layers 88 include silicon nitride layer 88A, silicon layer 88B, and silicon nitride layer 88C. In accordance with alternative embodiments, a single-layer hard mask 88 is used, which may be formed of or comprise silicon nitride.

Etching mask 90 is then formed, as shown in FIG. 23. Etching mask 90 may also have a single-layer structure (which may include a photoresist) or a dual-layer structure including a Bottom Anti-reflective Coating (BARC) and a photoresist. Alternatively, etching mask 90 may have a tri-layer, which may include a bottom layer, a middle layer over the bottom layer, and a top layer, which may be a patterned photoresist. Trench 92 is formed in etching mask 90.

Next, etching mask 90 is used to etch mask layers 88, so that trench 92 extends into hard mask layers 88. The etching may be anisotropic. In accordance with some embodiments, trench 92 extends to the top surface of hard mask. Etching mask 90 may be removed after trench 92 is formed in hard mask layers 88.

Next, as also shown in FIG. 23, the replacement gate stack 70 is etched. The etching of replacement gate stack 70 is anisotropic. In accordance with some embodiments, the etching is performed until STI region 26 is exposed. Trench 92 may or may not extend into STI region 26. After the etching process, hard mask layers 88 may (or may not) be removed. Gate stack 70 is thus separated into gate stacks 70A and 70B.

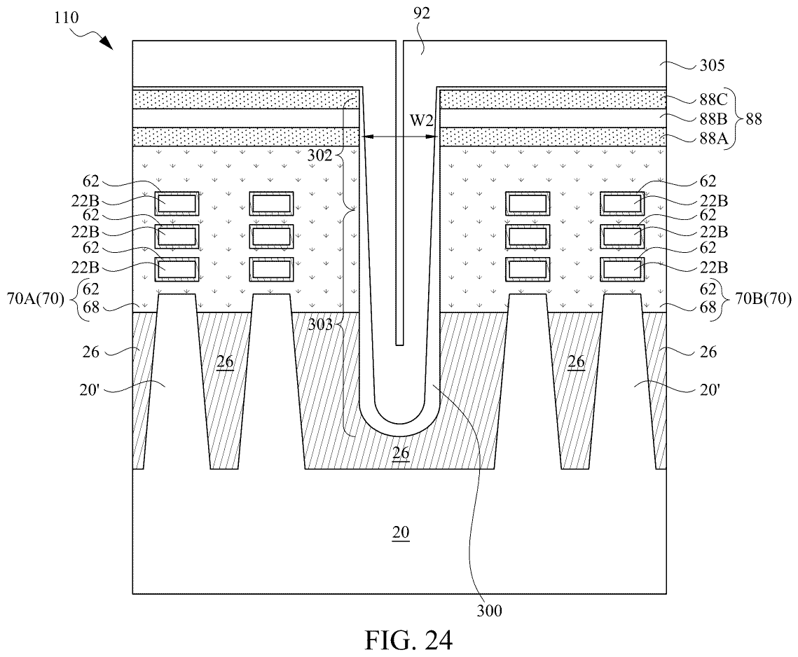

FIGS. 24-32 illustrate embodiments of a method for forming a buffer layer 300 within the trench 92 for forming CMG isolation regions 110. Similar to the buffer layer 300 that is used in the fin isolation regions 112 (also referred to as CPODE isolation region), the buffer layer 300 used in the CMG isolation regions 110 can mitigate induced charge in the well that is present in the substrate 20 from the fixed charge of an isolating material without narrowing the width W2 of the opening to the trench 92, e.g., without narrowing the critical dimension (CD) of the opening to the trench 92. To avoid narrowing of the width W2 of the opening to the trench 92, the methods and structures described with reference to FIGS. 24-32 employ a bottom up deposition approaches that form a greater amount of material for the buffer layer 300 in the bottom of the trench 92 than the amount of material for the buffer layer 300 in the top of the trench 92. This reduces the incidence of pinch off for the opening to the trench 92.

FIG. 24 illustrates the formation of a buffer layer 300 that is formed by a cyclic set of inhibition and deposition steps, which together can provide a dense thick buffer layer 300 at the base of the trench 92 while limiting growth of the buffer layer 300 at the upper portion 302 of the trench 92. FIG. 24 illustrates an embodiment, in which a seam is present in the lower portion 303 of the trench 92. The buffer layer 300 that is depicted in FIG. 24 for the CMG isolation regions 110 is similar to the buffer layer 300 that is described above with reference to FIGS. 17C and 17D for use in fin isolation regions 112 (Continuous Polysilicon on Diffusion edge (CPODE) regions). Therefore, the above description of the buffer layer 300 that is described above for FIGS. 17C and 17D is suitable for the description of the buffer layer 300 that is illustrated in FIG. 24, in which elements having the same reference numbers may share descriptions for their details.

For example, the buffer layer 300 depicted in FIG. 24 may be formed following an inhibition treatment applied to the trenches 92 that includes one or more passivation treatment or a thermal treatment that is applied to an upper portion 302 of the trench 92. In some embodiments, when the inhibition treatment 301 is a thermal treatment, the thermal treatment may include a temperature greater than 600° C. in an inert gas atmosphere comprising hydrogen, helium, nitrogen or combinations thereof, wherein the thermal treatment includes a pressure ranging from 10 Torr to 5 ATM. In some embodiments, when the inhibition treatment 301 is a plasma treatment, the plasma treatment may include a plasma include argon, helium, hydrogen, or combinations thereof, wherein a temperature for the plasma treatment ranges from 300° C. to 500° C., wherein the plasma treatment includes a pressure ranging from 10 Torr to 5 ATM. Similar to the embodiment described above with referenced to FIG. 17C, the process conditions for forming the buffer layer 300 depicted in FIG. 24 can be selected to provide that only the upper portion 302 of the trench 92 is treated. Following the inhibition treatment, the exposed sidewalls of the trench 92 through the interlevel dielectric layer (ILD) 52 have a high concentration of silicon to hydrogen (Si—H) bonds, silicon to oxygen (Si—O) bonds, and silicon to silicon (Si—Si bonds) after removing the hydroxyl (—OH) groups, which will inhibit the formation of dielectric materials that are attempted to be formed directly thereon. The inhibition treatment is passivation treatment that has been applied to an upper portion 302 of the trench 92.

Following the inhibition treatment (passivation treatment), a non-conformal material layer having a lower fixed charge concentration than silicon nitride is formed for the buffer layer 300 within the trench 92. For example, the non-conformal material layer may be composed of silicon oxide (SiO2), silicon oxynitride (SiON), silicon oxycarbon nitride (SiCON) or combinations thereof. The non-conformal material layer has a first portion on the upper portion 302 of the trench 92 passivated by the at least one passivation treatment (also referred to an inhibition treatment), and the non-conformal layer has a second portion that in a lower portion 303 of the trench 92 that extends to the trench's base. The first portion of the non-conformal material layer for the buffer layer 300 in the upper portion 302 of the trench 92 has a lesser thickness than the second portion of the non-conformal material layer for the buffer layer 300 in the lower portion 303 of the trench 92. For example, the difference in the thickness between the first portion of the non-conformal material layer for the buffer layer 300 that is in the upper portion 302 of the trench 92, and the second portion of the non-conformal layer for the buffer layer 300 in the lower portion 303 of the trench 92 ranges from 2 nm to 10 nm.

Similar to the embodiment described above with referenced to FIG. 17C, the process conditions for forming the buffer layer 300 depicted in FIG. 24 can be selected to provide that only the upper portion 302 of the trench 92 is treated with the inhibition step. Following the inhibition step, the buffer layer 300 may deposited using plasma enhanced chemical vapor deposition (PECVD), atomic layer deposition (ALD), and/or plasma enhanced atomic layer deposition (PEALD).

It is noted that the inhibition step depicted in FIG. 24 and the deposition step depicted in FIG. 24 are stages of a cycle that may be repeated to provide a bottom up fill of a non-conformal material layer having a lower fixed charge concentration than silicon nitride. For example, the cycle of the inhibition and deposition steps depicted in FIG. 24 may be repeated 2 times to 100 times. However, the number of repetitions for the cycle of the inhibition step and the deposition step may be repeated any number of times to provide the appropriate amount of material for the buffer layer 300 in the base of the trench 92.

Still referring to FIG. 24, following the formation of the buffer layer 300, a fill dielectric 305 may be deposited on the buffer layer 300. The fill dielectric 305 that is depicted in FIG. 24 is similar to the fill dielectric 305 that has been described above with reference to FIG. 17I. Therefore, the description of the fill dielectric 305 that is depicted in FIG. 17I is suitable for the description of the fill dielectric 305 that fills the trench 92 depicted in FIG. 24. For example, the fill dielectric 305 may be composed of silicon nitride.

After the deposition of fill dielectric 305, a planarization process such as a CMP process or a mechanical grinding process is performed. The planarization process may be stopped on the top surfaces of gate stacks 70. The remaining portions of buffer layer 300 and the fill dielectric 305 are collectively referred to as CMG isolation region 110 hereinafter, as shown in FIG. 24. Due to the separation of the CMG isolation regions 110 from fin isolation regions 112, there may be some regions separating the CMG isolation regions 110 from their neighboring fin isolation regions 112 (also referred to as CPODE isolation regions). The lengths of CMG isolation regions 110 may be selected depending on the layout of the circuit.

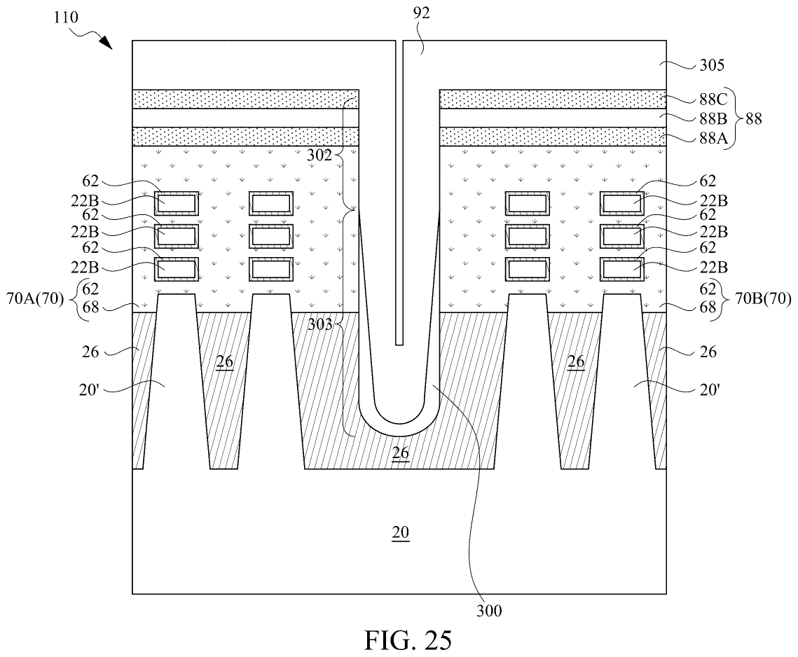

FIG. 25 illustrates another embodiment of a CMG isolation region 100, in which the formation of a buffer layer 300 includes a cyclic set of inhibition and deposition steps, which together can provide a dense thick buffer layer 300 at the base of the trench 92. In the embodiment depicted in FIG. 25, the inhibition step is more aggressive than in the embodiment depicted in FIG. 24. Because of the greater degree of passivation of the upper portion 302 or the trench 92, the buffer layer 300 will not be formed on the upper portion 302 for the trench 92 for the embodiment that is depicted in FIG. 25. The conditions for the inhibition step for forming the buffer layer 300 for the embodiment that is depicted in FIG. 25 are further described above with reference to FIG. 17F.

The geometries for the buffer layers for the CMG isolation regions 110 that are illustrated in the embodiments depicted in FIGS. 24 and 25 may also be formed using a process sequence that includes the deposition of a buffer layer 300 with a conformal or directional deposition process (without the use of an inhibition step) followed by an etching step, in which the etching step produces a non-conformal thickness for the buffer layer 300. More particularly, a method for forming a non-conformal thickness buffer layer 300 in the trench 92 for the CMG isolation regions 110 using a cycle of deposition and etching steps may include forming a buffer layer 300 having a lower fixed charge concentration than silicon nitride, and etching the buffer layer 300 to produce a non-conformal thickness, wherein the non-conformal thickness of the buffer layer 300 includes a first portion in an first portion 302 of the trench 92 having a lesser thickness than a second portion of the buffer layer 300 in a second portion 303 of the trench 92.

The deposition steps for forming the geometry of the buffer layer 300 depicted in FIGS. 24 and 25 has been described above with reference to FIG. 17G. The etching step for forming the buffer layer 300 depicted in FIG. 24 has been described above with reference to FIG. 17H. The etch process for the etching step may be adjusted to remove the entirety of the buffer layer 300 from the first portion 302 of the trench 92, as depicted in FIG. 25. In some embodiments, the etching step for forming the buffer layer 300 depicted in FIG. 25 has been described above with reference to FIG. 17J. Following the cycle of deposition and etch steps for forming the buffer layer 300, the trench 92 may be filled with a fill dielectric 305, which may be planarized.

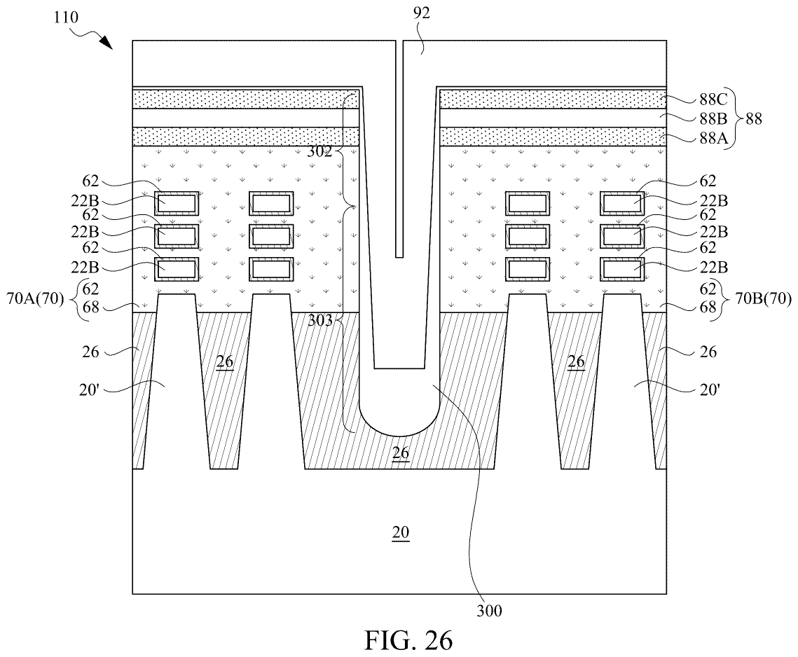

FIGS. 26-28 illustrate other embodiments of the CMG isolation region 110 including the buffer layer 300 having a non-conformal thickness that provides a thick portion of low fixed charge level dielectric material in the base of the trench 92, while not pinching off the upper portion 302 of the trench 92. In the embodiments depicted in FIGS. 26-28, a directional deposition is performed in combination with an etch step to configure the geometry of the material for the buffer layer 300 at the base of the trench 92. For each of the embodiments depicted in FIGS. 26-28 the etch processes have been described above with reference to FIG. 17H.

For example, FIG. 26 illustrates an embodiment of a buffer layer 300 that produces a greater thickness for the buffer layer 300 in the lower portion 303 of the trench 92 when compared to the thickness for the buffer layer 300 in the upper portion 302 of the trench 92. The portion of the buffer layer 300 at the base of the lower portion 303 of the trench 92 has a flat upper surface. The flat upper surface can be formed by adjusting the deposition conditions of the directional deposition process for forming the buffer layer 300, as described above with reference to FIG. 17K. The fill dielectric 305 is formed directly atop the buffer layer 300.

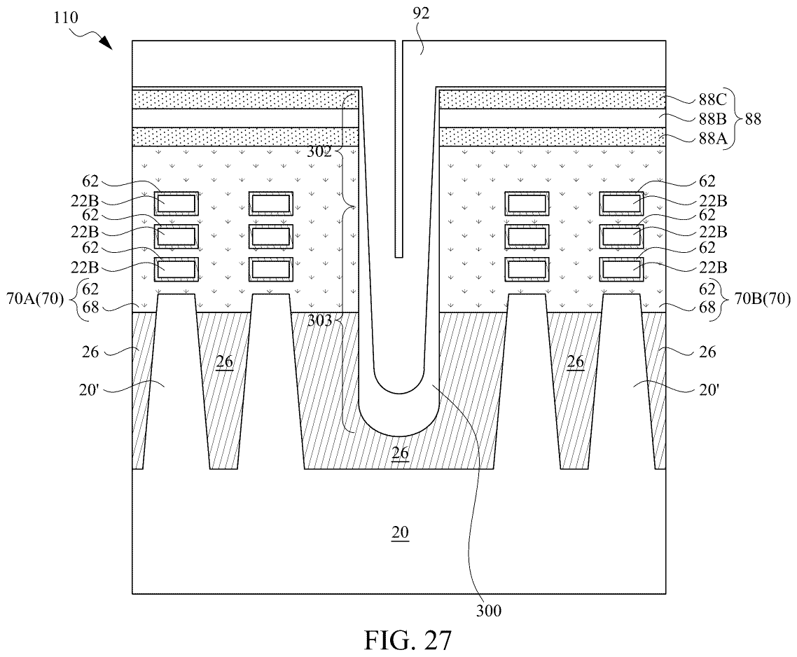

FIG. 27 illustrates an embodiment of a buffer layer 300 that is formed using a cycle of a directional deposition and an etch process to produce a greater thickness for the buffer layer 300 in the lower portion 303 of the trench 92. In the embodiment that is depicted in FIG. 27, the directional deposition process for forming the buffer layer 300 produces a greater thickness for the buffer layer 300 in the lower portion 303 of the trench 92 when compared to the thickness for the buffer layer 300 in the upper portion 302 of the trench 92, wherein the portion of the buffer layer 300 at the base of the lower portion 303 of the trench 92 has a convex upper surface. The convex upper surface can be formed by adjusting the deposition conditions of the directional deposition process for forming the buffer layer 300, as described above with reference to FIG. 17L. The fill dielectric 305 is formed directly atop the buffer layer 300.

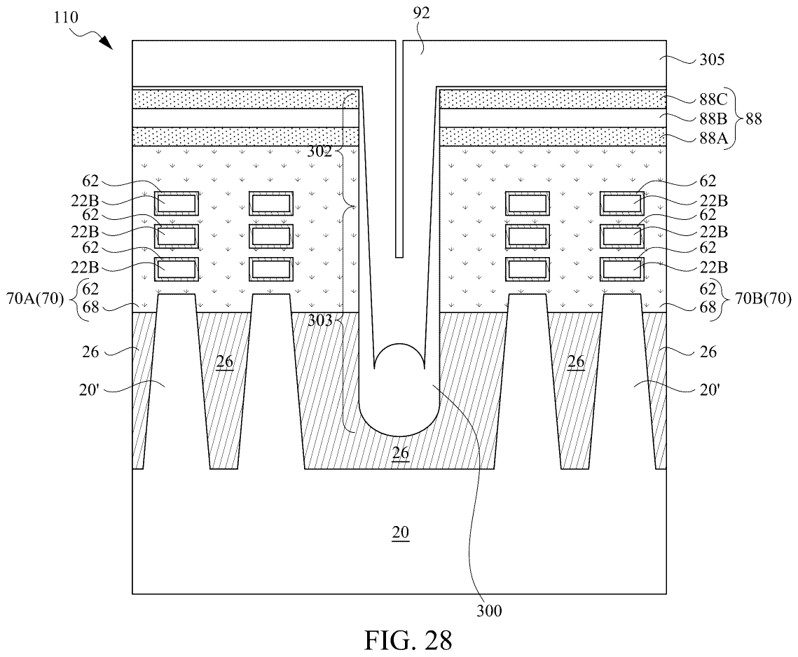

FIG. 28 illustrates an embodiment of a buffer layer 300 for a CMG isolation region 110, in which the buffer layer 300 is formed using a cycle of a directional deposition and an etch process to produce a greater thickness for the buffer layer 300 in the lower portion 303 of the trench 92. In the embodiment that is depicted in FIG. 28, the directional deposition process for forming the buffer layer 300 produces a greater thickness for the buffer layer 300 in the lower portion 303 of the trench 92 when compared to the thickness for the buffer layer 300 in the upper portion 302 of the trench 92, wherein the portion of the buffer layer 300 at the base of the lower portion 303 of the trench 92 has a concave upper surface. The concave upper surface can be formed by adjusting the deposition conditions of the directional deposition process for forming the buffer layer 300, as described above with reference to FIG. 17M. The fill dielectric 305 is formed directly atop the buffer layer 300.

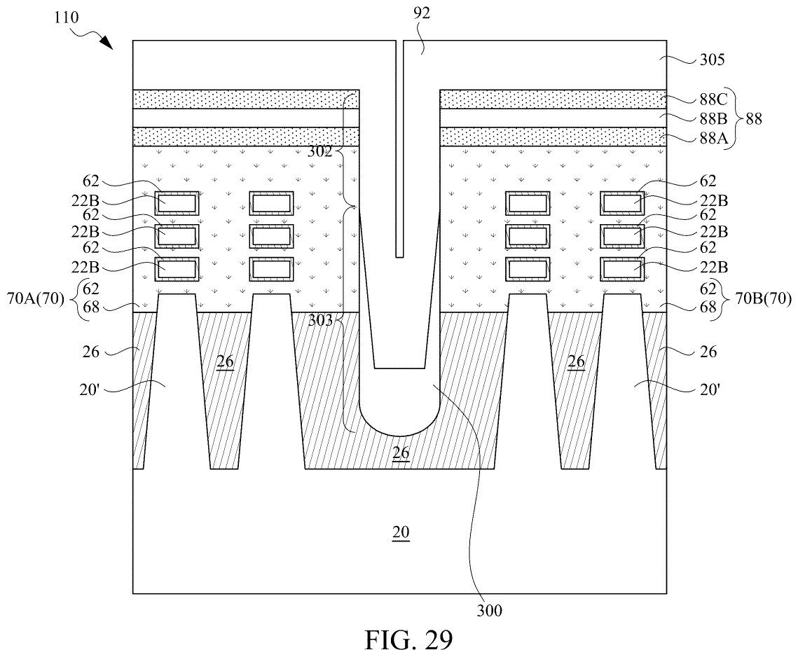

FIGS. 29-31 illustrate other embodiments of CMG isolation regions 110 that have been formed including a buffer layer 300 having a thick portion of low fixed charge level dielectric material at the base of the trench 92 for the CMG isolation region 110. In the embodiments depicted in FIGS. 29-31, the buffer layer 300 is formed by a cycle of deposition and etching steps, in which the aggressiveness of the etching step has been adjusted to remove the entirety of the buffer layer 300 from the upper portion 302 of the trench 92, while a thick portion of the buffer layer 300 remains at the base of the lower portion 303 of the trench 92. In the embodiments depicted in FIGS. 29-31, the buffer layer 300 is deposited using a directional deposition process. The etch process for removing the buffer layer 300 from the upper portion 302 of the trench 92 is described about with reference to FIG. 17J.

FIG. 29 illustrates an embodiment of a buffer layer 300 that is formed by the combination of a directional deposition process, as described above with reference to FIG. 26, and an etch process, as described above with reference to FIG. 17J. The directional deposition process for forming the buffer layer 300 depicted in FIG. 29 produces a greater thickness for the buffer layer 300 in the lower portion 303 of the trench 92. The portion of the buffer layer 300 at the base of the lower portion 303 of the trench 118 has a flat upper surface. The buffer layer 300 depicted in FIG. 29 has been removed from an entirety of the upper portion 302 of the trench 92. The fill dielectric 305 is formed directly atop the buffer layer 300.

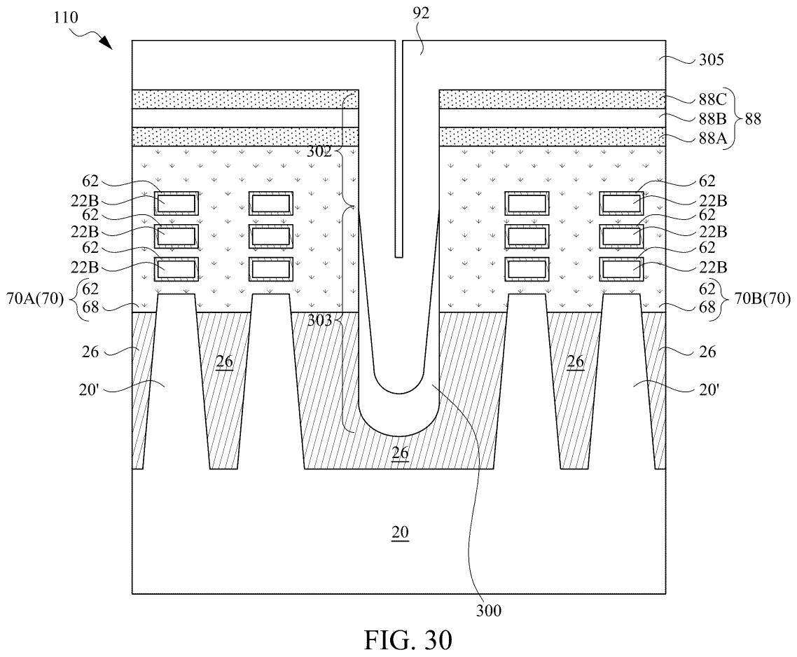

FIG. 30 illustrates a buffer layer 300 that was formed by a direction deposition step, as described with reference to FIG. 27 in combination with an aggressive etch process, as described with reference to FIG. 17J. The buffer layer 300 depicted in FIG. 30 has been removed from an entirety of the upper portion 302 of the trench 92 for the CMG isolation region 110, and includes a thick portion for the buffer layer 300 in the lower portion 303 of the trench 92 having a convex upper surface. The fill dielectric 305 is formed directly atop the buffer layer 300.

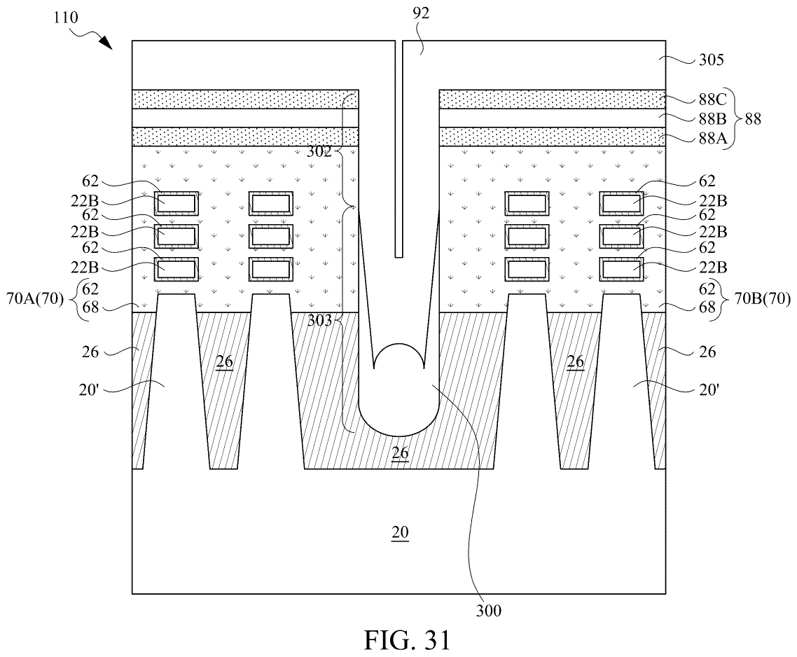

FIG. 31 illustrates a buffer layer 300 for a CMG isolation region 110 that was formed by a direction deposition step, as described with reference to FIG. 28 in combination with an aggressive etch process, as described with reference to FIG. 17J. The buffer layer depicted in FIG. 31 has been removed from an entirety of the upper portion 302 of the trench 92, and includes a thick portion for the buffer layer 300 in the lower portion 303 of the trench 92 having a concave upper surface. The fill dielectric 305 is formed directly atop the buffer layer 300.

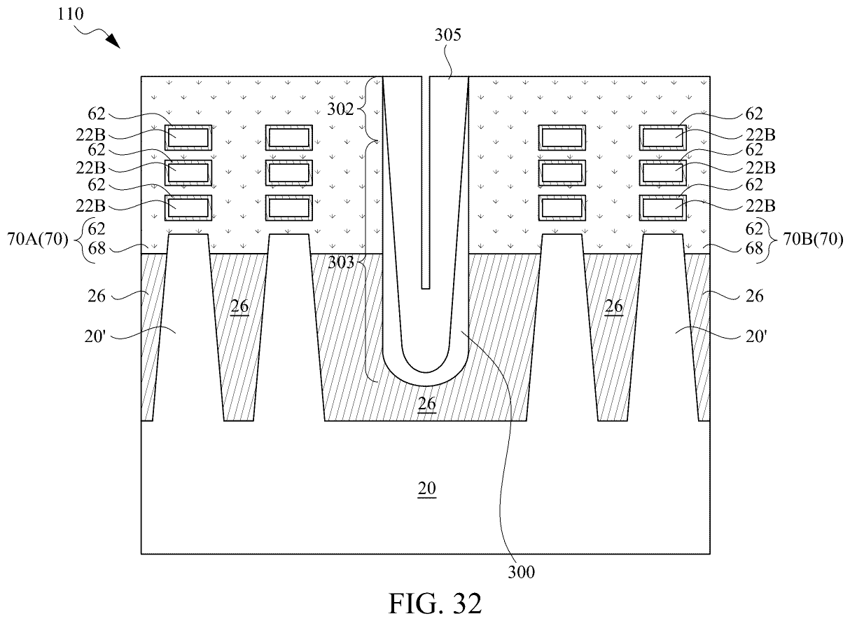

FIG. 32 illustrates one embodiment of a planarization process being applied to the portions of the buffer layer 300 and the fill dielectric 305 that extend outside the trench 92 for the CMG isolation region 110. The planarization process may include chemical mechanical planarization (CMP). It is noted that although FIG. 32 illustrates a planarization process being applied to buffer layer 300 and fill dielectric 305 for the embodiment depicted in FIG. 24, the planarization process depicted in FIG. 32 is equally applicable to any of the embodiments described with reference to FIGS. 24-31.

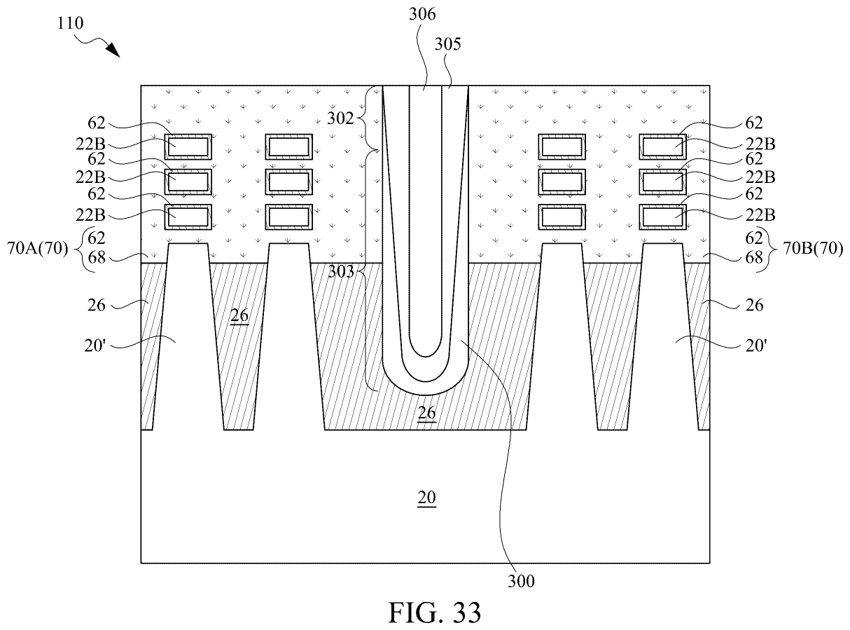

FIGS. 33-36 depict another embodiment of how the buffer layer 300 may be integrated into the trench 92 of a CMG isolation region 110. In the embodiments described above, following the formation of the buffer layer 300, the fill dielectric 305 is deposited filling the trench 92. In some embodiments, it is not necessary that the fill dielectric 305 fill the entirety of the trench. In the embodiments depicted in FIGS. 33-36, following the formation of the fill dielectric 305, a low-k dielectric fill material 306 may be deposited filling the trench 92. The integration of the low-k dielectric fill material 306 may reduce the incidence of parasitic capacitance with the area surrounding the isolation structure. In this embodiment, the fill dielectric 305 may have the geometry of a liner, and the low-k dielectric fill material 306 may be a fill material that fills the remaining open portion of the trench 92. In some embodiments, the low-k dielectric fill material 306 is composed of silicon oxide (SiO2). However, in other embodiments, the low-k dielectric fill material 306 may be composed of any material having the dielectric constant of silicon oxide at room temperature, e.g., approximately 4.0, or less. The low-k dielectric fill material 306 may be deposited by chemical vapor deposition, e.g., plasma enhanced chemical vapor deposition (PECVD) and/or atomic layer deposition (ALD), e.g., plasma enhanced atomic layer deposition (ALD).

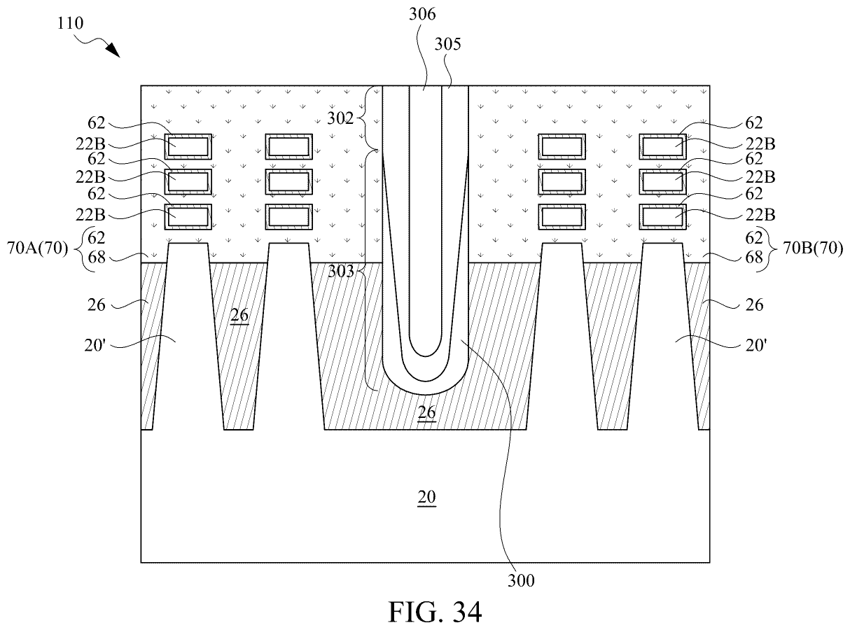

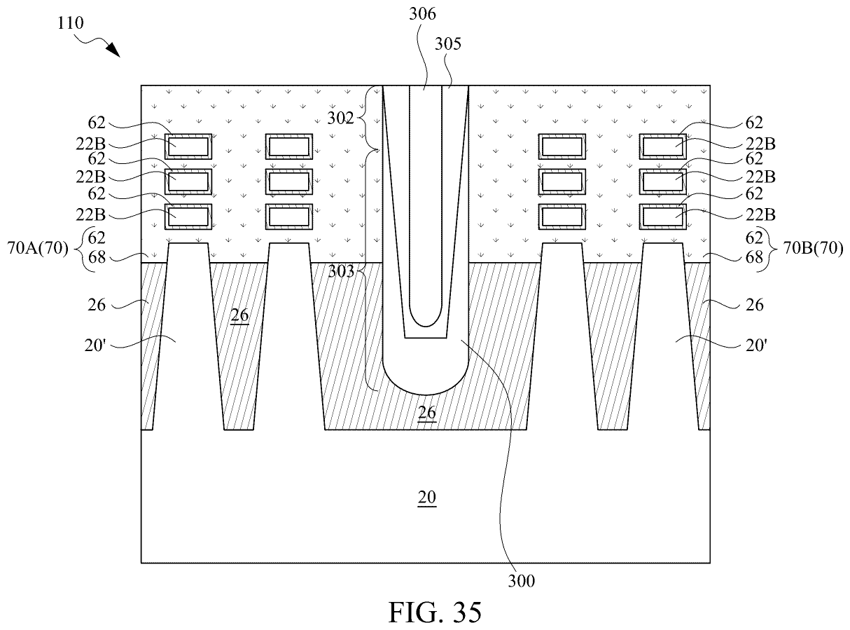

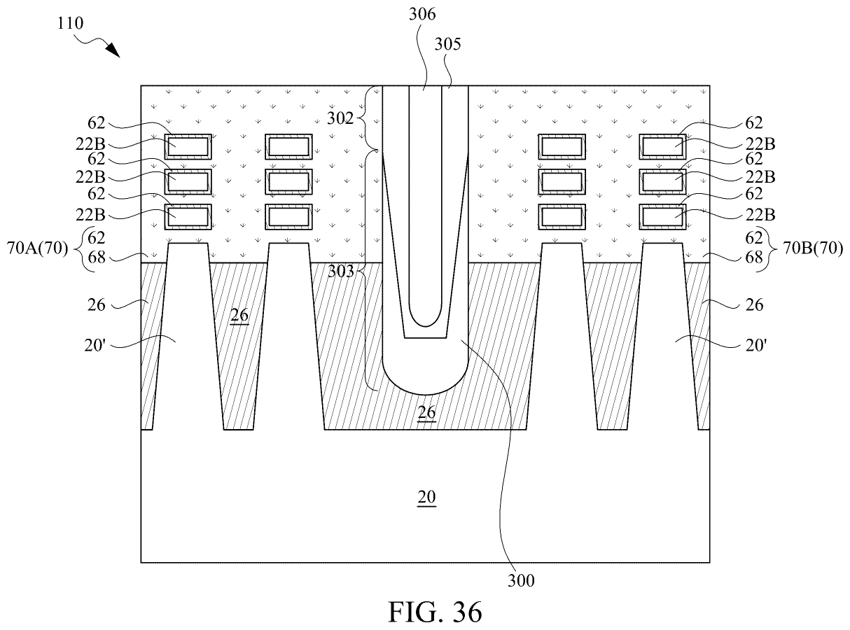

FIG. 33 illustrates one embodiment of a low-k dielectric fill material 306 being integrated onto a fill dielectric 305 that is present over a buffer layer 300 that was formed using a deposition and etch cycle as described above with reference to FIG. 24. FIG. 34 illustrates one embodiment of a low-k dielectric fill material 306 being integrated onto a fill dielectric 305 that is present over a buffer layer 400 that was formed using a deposition and etch cycle as described above with reference to FIG. 25. In the embodiment depicted in FIG. 34, the buffer layer 300 is removed from the entire upper portion 302 of the trench 92. FIG. 35 illustrates one embodiment of a low-k dielectric fill material 306 being integrated onto a fill dielectric 305 that is present over a buffer layer 400 that was formed using a deposition and etch cycle as described above with reference to FIG. 26. The buffer layer depicted in FIG. 35 have a thick portion of low fixed charge level dielectric composition material having at the base of the trench 92 having a flat upper surface. FIG. 36 illustrates one embodiment of a low-k dielectric fill material 306 being integrated onto a fill dielectric 305 that is present over a buffer layer 400 that was formed using a deposition and etch cycle as described above with reference to FIG. 29. The buffer layer 300 has been entirely removed from the upper portion 302 of the trench 92. The buffer layer 300 depicted in FIG. 36 have a thick portion of low fixed charge level dielectric composition material having at the base of the trench 92 having a flat upper surface.

Although the low-k dielectric fill material 306 is integrated into the isolation structures of the cut metal gate (CMG) regions 110, the low-k dielectric fill material 306 is not limited to only these embodiments. For example, the low-k dielectric fill material 306 may also be employed as the fill material atop the fill dielectric 305 within the openings 118 for the fin isolation regions 112 (using CPODE processes). It is noted that the low-k dielectric fill material 306 may be integrated into any of the embodiments described herein, such as the embodiments described with reference to FIGS. 17E, 17F, 17I-17P and 24-32.

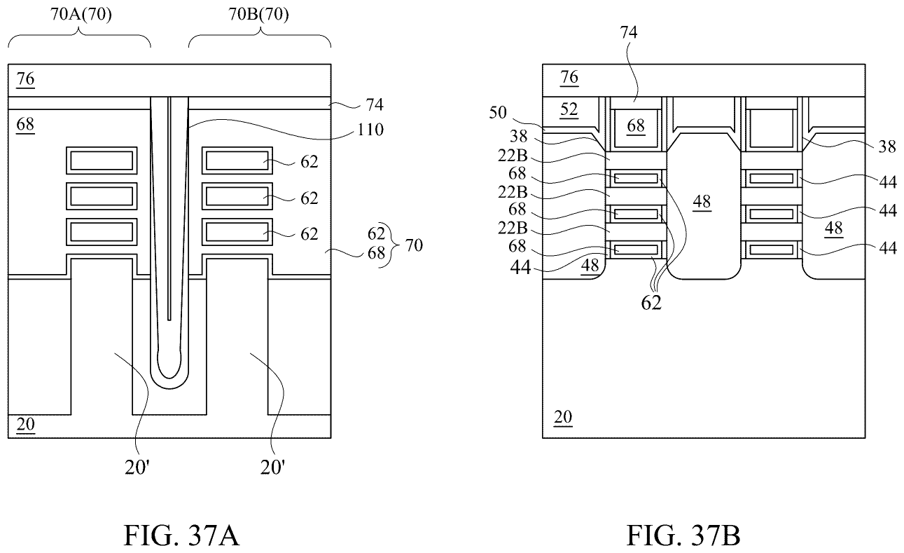

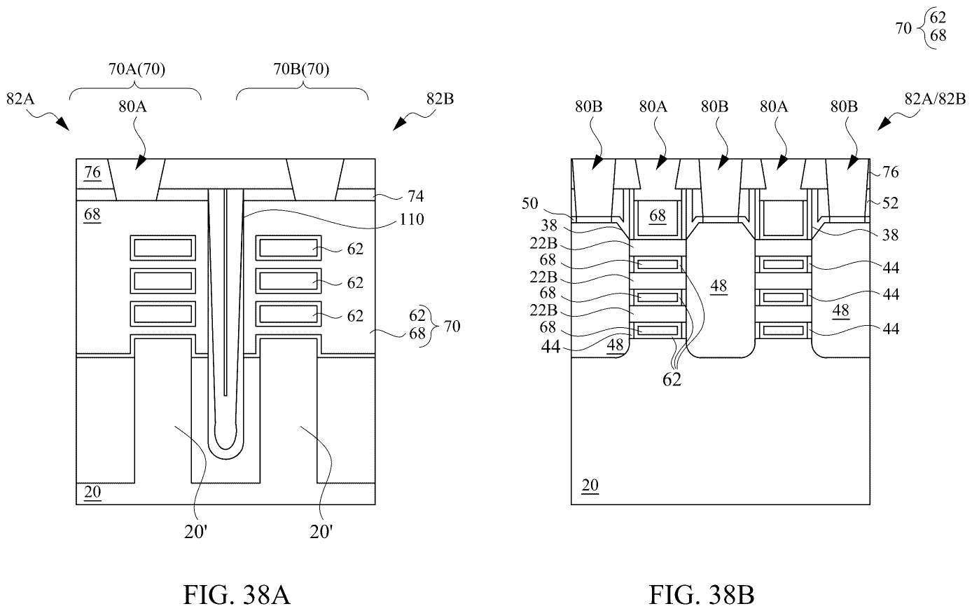

After the process as shown in FIG. 36, the remaining processes as shown in FIGS. 37A, 37B, 38A, and 38B are performed to finish the formation of the transistors.

FIG. 37A illustrates a cross-sectional of the structure shown in FIG. 21, in which CMG isolation region 110 has been formed to cut long metal gate stacks 70 into metal gate stacks (portions) 70A and 70B. Although the CMG isolation region 110 is depicted consistent with FIG. 32, any embodiment of the CMG isolation regions 110 described herein is applicable, such as the embodiments described with reference to FIGS. 24-36. Next, as also shown in FIGS. 37A and 37B, gate stacks 70 are recessed, so that recesses (occupied by CMG isolation region 110) are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 37A and 37B, ILD 76 is deposited over ILD 52 and over gate masks 74. The respective process is illustrated as process 230 in the process flow 200 shown as in FIG. 39. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

In FIGS. 38A and 38B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process(es), such as RIE, NBE, or the like.

After the recesses are formed, silicide regions 78 are formed over source/drain regions 48. The respective process is illustrated as process 232 in the process flow 200 shown as in FIG. 39. Contact plugs 80B are then formed over silicide regions 78. Also, contacts 80A (may also be referred to as gate contact plugs) are formed in the recesses, and are over and contacting gate electrodes 68. The respective process is illustrated as process 234 in the process flow 200 shown as in FIG. 39. Transistors 82A and 82B are thus formed. Although FIG. 38B illustrates that contact plugs 80A and 80B are in a same cross-section, in various embodiments, contact plugs 80A and 80B may be formed in different cross-sections, thereby reducing the risk of shorting with each other.

The embodiments of the present disclosure have some advantageous features. In the methods and structures of the present disclosure, the buffer layer 300 for isolation regions is formed using bottom-up deposition techniques is proposed to prevent induced charge in an isolation structure. In some embodiments, the buffer layer 300 can be selectively deposited from the bottom without blocking a gap opening.

In an embodiment, a method comprising: etching at least one conductive structure to form an opening separating the conductive structure into shorter portions; applying at least one passivation treatment to an upper portion of the opening; forming a non-conformal material layer having a first fixed charge concentration, wherein the non-conformal material layer has a first portion on the upper portion of the opening passivated by the at least one passivation treatment, and the non-conformal material layer has a second portion that extends to a base of the opening, the first portion of the non-conformal material layer having a lesser thickness than the second portion of the non-conformal material layer; and depositing a fill dielectric having a second fixed charge concentration, higher than the first fixed charge concentration on the non-conformal material layer.

In an embodiment, the at least one conductive structure comprises a plurality of semiconductor regions. In an embodiment, the at least one conductive structure comprises gate structures that are present on semiconductors regions. In an embodiment, the non-conformal material layer comprises silicon oxide (SiO2), silicon oxynitride (SiON), or silicon oxycarbon nitride (SiCON). In an embodiment, the passivation treatment is a thermal treatment comprising a temperature greater than 600° C. in an inert gas atmosphere comprising hydrogen, helium, nitrogen or combinations thereof, wherein the thermal treatment includes a pressure ranging from 10 Torr to 5 ATM. In an embodiment, the passivation treatment is a plasma treatment including a plasma comprising argon, helium, hydrogen, or combinations thereof, wherein the plasma treatment includes a temperature ranging from 300° C. to 500° C., wherein the plasma treatment includes a pressure ranging from 10 Torr to 5 ATM. In an embodiment, a difference in thickness between the first portion of the non-conformal material layer and the second portion of the non-conformal material layer ranges from 2 nm to 10 nm.

In an embodiment, a method comprising: etching at least one conductive structure to form an opening separating the conductive structure into shorter portions; forming a buffer layer having a lower fixed charge concentration than silicon nitride; etching the buffer layer to produce a non-conformal thickness, wherein the non-conformal thickness of the buffer layer includes a first portion in an upper portion of the opening having a lesser thickness than a second portion of the buffer layer in a base portion of the opening; and depositing a fill dielectric on the buffer layer having the non-conformal thickness. In an embodiment, the buffer layer comprises silicon oxide (SiO2), silicon oxynitride (SiON), or silicon oxycarbon nitride (SiCON). In an embodiment, the etching comprises a fluorine based etchant. In an embodiment, the etching comprises a plasma etch that includes a pressure ranging from 10 Torr to 30 Torr, a temperature ranging from 300° C. to 500° C., and plasma having a greater ratio of radicals to ions. In an embodiment, the forming of the buffer layer comprises a directional deposition. In an embodiment, the forming of the buffer layer comprises a conformal deposition. In an embodiment, the method further comprises forming a low-k dielectric fill on the fill dielectric, wherein the fill dielectric comprises silicon nitride.

In an embodiment, a structure comprising: at least one conductive feature; a trench extending through the conductive feature; and a trench fill comprising: a non-conformal material layer having a lower fixed charge concentration than silicon nitride, wherein the non-conformal material layer has a first portion on an upper portion of the trench having a first thickness, and the non-conformal material layer has a second portion that extends to a base of the trench having a second thickness, wherein the second thickness is less than the first thickness; and a fill dielectric on the non-conformal material layer. In an embodiment, the at least one conductive feature is a gate structure. In an embodiment, the at least one conductive feature is a stack of nanosheets. In an embodiment, the non-conformal material comprises silicon oxide (SiO2), silicon oxynitride (SiON), or silicon oxycarbon nitride (SiCON). In an embodiment, a difference in thickness between the first thickness and the second thickness ranges from 2 nm to 10 nm. In an embodiment, the fill dielectric comprises silicon nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
etching at least one conductive structure to form an opening separating the conductive structure into shorter portions;
applying at least one passivation treatment to an upper portion of the opening; forming a non-conformal material layer having a first fixed charge concentration, wherein the
non-conformal material layer has a first portion on the upper portion of the opening passivated by the at least one passivation treatment, and the non-conformal material layer has a second portion that extends to a base of the opening, the first portion of the non-conformal material layer having a lesser thickness than the second portion of the non-conformal material layer; and
depositing a fill dielectric having a second fixed charge concentration, higher than the first fixed charge concentration on the non-conformal material layer.

2. The method of claim 1, wherein the at least one conductive structure comprises a plurality of semiconductor regions.

3. The method of claim 1, wherein the at least one conductive structure comprises gate structures that are present on semiconductors regions.

4. The method of claim 1, wherein the non-conformal material layer comprises silicon oxide (SiO₂), silicon oxynitride (SiON), or silicon oxycarbon nitride (SiCON).

5. The method of claim 1, wherein the passivation treatment is a thermal treatment comprising a temperature greater than 600° C. in an inert gas atmosphere comprising hydrogen, helium, nitrogen or combinations thereof, wherein the thermal treatment includes a pressure ranging from 10 Torr to 5 ATM.

6. The method of claim 1, wherein the passivation treatment is a plasma treatment including a plasma comprising argon, helium, hydrogen, or combinations thereof, wherein the plasma treatment includes a temperature ranging from 300° C. to 500° C., wherein the plasma treatment includes a pressure ranging from 10 Torr to 5 ATM.

7. The method of claim 1, wherein a difference in thickness between the first portion of the non-conformal material layer and the second portion of the non-conformal material layer ranges from 2 nm to 10 nm.

8. A method comprising:
etching at least one conductive structure to form an opening separating the conductive structure into shorter portions;
forming a buffer layer having a lower fixed charge concentration than silicon nitride; etching the buffer layer to produce a non-conformal thickness, wherein the non-conformal thickness of the buffer layer includes a first portion in an upper portion of the opening having a lesser thickness than a second portion of the buffer layer in a base portion of the opening; and
depositing a fill dielectric on the buffer layer having the non-conformal thickness.

9. The method of claim 8, wherein the buffer layer comprises silicon oxide (SiO₂), silicon oxynitride (SiON), or silicon oxycarbon nitride (SiCON).

10. The method of claim 8, wherein the etching comprises a fluorine based etchant.

11. The method of claim 8, wherein the etching comprises a plasma etch that includes a pressure ranging from 10 Torr to 30 Torr, a temperature ranging from 300° C. to 500° C., and plasma having a greater ratio of radicals to ions.

12. The method of claim 8, wherein the forming of the buffer layer comprises a directional deposition.

13. The method of claim 8, wherein the forming of the buffer layer comprises a conformal deposition.

14. The method of claim 8, further comprising forming a low-k dielectric fill on the fill dielectric, wherein the fill dielectric comprises silicon nitride.

15. A structure comprising:
at least one conductive feature;
a trench extending through the conductive feature; and
a trench fill comprising:
a non-conformal material layer having a first fixed charge concentration, wherein the non-conformal material layer has a first portion on an upper portion of the trench having a first thickness, and the non-conformal material layer has a second portion that extends to a base of the trench having a second thickness, wherein the second thickness is less than the first thickness; and
a fill dielectric having a second fixed charge concentration, higher than the first fixed charge concentration on the non-conformal material layer.

16. The structure of claim 15, wherein the at least one conductive feature is a gate structure.

17. The structure of claim 15, wherein the at least one conductive feature is a stack of nanosheets.

18. The structure of claim 15, wherein the non-conformal material layer comprises silicon oxide (SiO₂), silicon oxynitride (SiON), or silicon oxycarbon nitride (SiCON).

19. The structure of claim 15, wherein a difference in thickness between the first thickness and the second thickness ranges from 2 nm to 10 nm.

20. The structure of claim 15, wherein the fill dielectric comprises silicon nitride.
